(19) United States
(12) Patent Application Publication
(10) Pub. No.: US 2024/0114769 A1
(43) Pub. Date: Apr. 4, 2024

(54) COMPOSITION, FILM, LAMINATE, AND DISPLAY DEVICE

(71) Applicant: Sumitomo Chemical Company, Limited, Chuo-ku, Tokyo (JP)

(72) Inventor: Keisuke TAKAHASHI, Osaka-shi, Osaka (JP)

(21) Appl. No.: 18/272,180

(22) PCT Filed: Nov. 18, 2021
(86) PCT No.: PCT/JP2021/042413

§ 371 Date: Jul. 13, 2023

(30) Foreign Application Priority Data
Jan. 18, 2021 (JP) 2021-005846

(51) Int. Cl. H10K 85/40; C09K 19/20; C09K 19/30; H10K 85/60

(52) U.S. Cl. CPC H10K 85/40; C09K 19/2007; C09K 19/3068; H10K 85/615; H10K 85/633; C09K 2019/2035; C09K 2019/2078; C09K 2019/3075

(57) ABSTRACT

Disclosed is a composition including a compound of formula (1), a compound of formula (2) having a maximum absorption wavelength of 550 nm or more and 650 nm or less, and a liquid crystalline compound. n and m are 1 or 2. R¹ and R³ represent a substituent. R² and R⁴ represent an alkylamino group, an alkoxy group, or an alkylthio group. P represents a single bond, —OC(═O)—, —C(═O)O—, —NHC(═O)—, —C(═O)NH—, —C≡C—, —CH═CH—, —CH═N—, —N═N—, and —N═CH—. Ar¹, Ar², and Ar³ represent a 1,4-phenylene group or a divalent sulfur-containing aromatic heterocyclic group, and at least one of Ar¹ and Ar² is substituted with fluorine. Ar⁴, Ar⁵, and Ar⁶ represent a 1,4-phenylene group, a naphthalenediyl group, or a divalent sulfur-containing aromatic heterocyclic group.

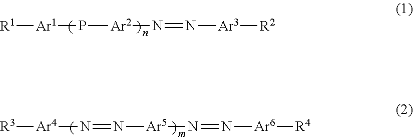

### BACKGROUND OF THE INVENTION

### Field of the Invention

The present invention relates to a composition, a film, a laminate, and a display device.

### Description of the Related Art

There is a continuous demand for reducing the thickness of displays such as image display panels, and a polarizing plate, a polarizer, and the like as constituent elements of the display are also required to be further reduced in thickness. In response to such a demand, for example, a thin host-guest type polarizer including a polarizing film containing a polymerizable liquid crystal compound and a dichroic dye compound has been proposed (see, for example, JP-T-2007-510946 and JP-A-2013-37353).

### SUMMARY OF THE INVENTION

In the host-guest type polarizer including a plurality of dyes, a dichroic ratio in a wavelength range of 570 nm or more and 700 nm or less may decrease due to photodegradation or the like of the polarizing film. An object of the present invention is to provide a composition capable of forming a polarizing film in which a decrease in dichroic ratio in a wavelength range of 570 nm or more and 700 nm or less is suppressed.

The present invention provides the following [1] to [8].

[1] A composition comprising: a first compound represented by the following formula (1); a second compound having a maximum absorption wavelength in a wavelength range of 550 nm or more and 650 nm or less and represented by the following formula (2); and a liquid crystalline compound containing at least one of a polymerizable liquid crystal compound and a liquid crystalline polymer compound.

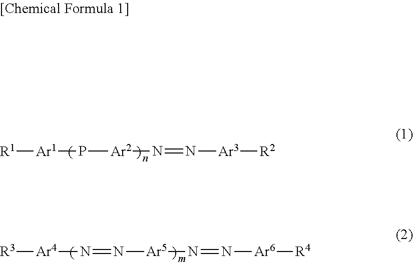

[In the formulae (1) and (2), n and m each independently represent 1 or 2.

R¹ and R³ each independently represent a substituent.

R² and R⁴ each independently represent one group selected from the group consisting of an alkylamino group, an alkoxy group, and an alkylthio group, and a hydrogen atom of these groups is optionally substituted with a polymerizable group.

P represents a single bond or at least one group selected from the group consisting of —OC(═O)—, —C(═O)O—, —NHC(═O)—, —C(═O)NH—, —C≡C—, —CH═CH—, —CH═N—, —N═N—, and —N═CH—.

Ar¹, Ar², and Ar³ each independently represent a 1,4-phenylene group or a divalent sulfur-containing aromatic heterocyclic group optionally having, as a substituent, at least one selected from the group consisting of a halogen atom, a hydroxy group, a methyl group, and a methoxy group.

At least one of Ar¹ and Ar² has a fluorine atom as a substituent. Here, when Ar² has a fluorine atom and there are two Ar²s, at least one Ar² optionally has a fluorine atom.

Ar⁴, Ar⁵, and Ar⁶ each independently represent a 1,4-phenylene group, a naphthalenediyl group, or a divalent sulfur-containing aromatic heterocyclic group optionally having, as a substituent, at least one selected from the group consisting of a halogen atom, a hydroxy group, a methyl group, and a methoxy group.

When n is 2, two Ar²s and two Ps may be the same or different to each other.

When m is 2, two Ar⁵s may be the same or different to each other].

[2] The composition according to [1], wherein in the formula (2), at least one of Ar⁴, Ar⁵, and Ar⁶ represents a divalent sulfur-containing aromatic heterocyclic group.
[3] The composition according to [1] or [2], wherein in the formula (2), at least one of Ar⁴, Ar⁵, and Ar⁶ represents a thieno [2,3-d] thiazole-2,5-diyl group.
[4] The composition according to any one of [1] to [3], wherein in the formula (1), P represents a single bond or at least one group selected from the group consisting of —OC(═O)—, —C(═O)O—, —NHC(═O)—, —C(═O)NH—, and —N═N—.
[5] The composition according to any one of [1] to [4], wherein the liquid crystalline compound is a smectic liquid crystalline compound.
[6] A film including the composition according to any one of [1] to [5] as a forming material.
[7] A laminate including the film according to [6].
[8] A display device including the laminate according to [7].

According to the present invention, it is possible to provide a composition capable of forming a polarizing film in which a decrease in dichroic ratio in a wavelength range of 570 nm or more and 700 nm or less is suppressed.

### DETAILED DESCRIPTION OF THE PREFERRED EMBODIMENTS

The term “step” used herein encompasses not only an independent step but also a step which cannot be clearly distinguished from other steps, as long as the expected effect of the step is attained. When the composition contains plural substances corresponding to a particular component, the content of the particular component in the composition refers to the total amount of the plural substances present in the composition, unless otherwise specified. Hereinafter, an embodiment of the present invention will be described in detail. The scope of the present invention is not limited to the embodiment described herein, and various modifications can be made without departing from the spirit of the present invention.

### <Composition>

The composition according to the present embodiment includes a first compound represented by the following formula (1), a second compound having a maximum absorption wavelength in a wavelength range of 550 nm or more and 650 nm or less and represented by the following formula (2), and a liquid crystalline compound containing at least one of a polymerizable liquid crystal compound and a liquid crystalline polymer compound. The composition is used, for example, as a material for forming a polarizing film. That is, the composition may be a composition for forming a polarizing film. A polarizing plate including a polarizing film obtained using a composition as a forming material has improved light resistance, and can suppress a decrease in dichroic ratio associated with photodegradation in a wavelength range of 570 nm or more and 700 nm or less.

### First Compound

The composition contains at least one of the first compounds. The first compound has a structure represented by the formula (1), and has a fluorine atom as a substituent on at least one of Ar¹ and Ar². Thus, it is considered that the first compound exhibits excellent light resistance. It is considered that when the first compound exhibits excellent light resistance, for example, disturbance of alignment of a dye compound due to photodegradation in the polarizing film formed from the composition is suppressed, and the decrease in dichroic ratio in the wavelength range of 570 nm or more and 700 nm or less derived from the second compound can be suppressed. Although the second compound has, for example, a maximum absorption wavelength in the wavelength range of 550 nm or more and 650 nm or less in a solution state, it is considered that the absorption wavelength is shifted to a longer wavelength side by forming a polarizing film.

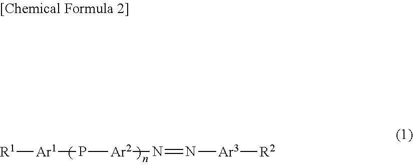

In the formula (1), R¹ represents a substituent. The substituent represented by R¹ may be, for example, a substituent containing at least an alkylene group, and may be a substituent in which a hydrogen atom or a polymerizable group is added to a divalent group formed from at least one selected from the group consisting of an alkylene group, an alkenediyl group, an oxygen atom, a sulfur atom, a carbonyl group, and a dialkylsilanediyl group. Examples of the substituent represented by R¹ include an alkyl group, an alkenyl group, an alkynyl group, an alkoxy group, an alkenyloxy group, an alkylthio group, an alkoxyalkylene group, an alkoxycarbonyl group, an alkylcarbonyloxy group, an alkoxycarbonylalkyleneoxycarbonyl group, an alkylcarbonyloxyalkylene group, a trialkylsilyloxyalkylene group, and a trialkylsilyloxyalkyleneoxy group, and the substituent represented by R¹ may be at least one selected from the group consisting of these groups. The substituent represented by R¹ may be a halogenated alkyl group such as a nitro group, a cyano group, or a perfluoroalkyl group, a halogen atom, or the like, and may be at least one selected from the group consisting of them. In one embodiment, the substituent represented by R¹ may be at least one selected from the group consisting of an alkyl group, an alkenyl group, an alkynyl group, an alkoxy group, an alkenyloxy group, an alkylthio group, an alkoxyalkylene group, an alkoxycarbonyl group, an alkylcarbonyloxy group, an alkoxycarbonylalkyleneoxycarbonyl group, an alkylcarbonyloxyalkylene group, a trialkylsilyloxyalkylene group, a trialkylsilyloxyalkyleneoxy group, a nitro group, a cyano group, a halogenated alkyl group, and a halogen atom.

The alkyl group contained in the substituent represented by R¹ may be linear or branched. The number of carbon atoms of the alkyl group contained in the substituent represented by R¹ may be, for example, 1 to 12, preferably 1 to 10, and more preferably 1 to 8. The number of carbon atoms of the alkylene group contained in the substituent represented by R¹ may be, for example, 1 to 12, preferably 1 to 10, and more preferably 1 to 8.

Specific examples of the alkyl group contained in the substituent represented by R¹ include a methyl group, an ethyl group, a propyl group, a butyl group, a 1-methylpropyl group, a 2-methylpropyl group, a pentyl group, a 2-methylbutyl group, a 3-methylbutyl group, a hexyl group, a 1,1-dimethyl-2-methylpropyl group, a heptyl group, a 1-ethylpentyl group, an octyl group, a 1-ethylhexyl group, a 2-ethylhexyl group, a nonyl group, and a 3,7-dimethyloctyl group. Specific examples of the alkylene group contained in the substituent represented by R¹ include a methylene group, an ethane-1,1-diyl group, an ethane-1,2-diyl group, a propane-1,3-diyl group, and a cyclohexane-1,4-diyl group.

At least one of the hydrogen atoms of the substituent represented by R¹ may be substituted with a polymerizable group. Here, examples of the polymerizable group include a (meth)acrylate group ((meth)acryloyloxy group), a vinylphenyl group, a vinyl group, and an epoxy group. The polymerizable group is preferably a radical polymerizable group, and among them, a (meth)acrylate group is preferable. When R¹ has a polymerizable group, the number thereof is, for example, 1 or 2, and preferably 1.

R² represents one group selected from the group consisting of an alkylamino group, an alkoxy group, and an alkylthio group, and is preferably an alkylamino group or an alkoxy group. The alkylamino group may be a monoalkylamino group or a dialkylamino group, and is preferably a dialkylamino group. R² is more preferably a dimethylamino group, a diethylamino group, an ethylmethylamino group, a pyrrolidyl group, a piperidyl group, a morpholinyl group, an oxazolidinyl group, a methoxy group, or an ethoxy group. At least one of the hydrogen atoms of the group represented by R² may be substituted with a polymerizable group. When R² has a polymerizable group, the number thereof is, for example, 1 or 2, and preferably 1.

Ar¹, Ar², and Ar³ each independently represent a 1,4-phenylene group optionally having a substituent or a divalent sulfur-containing aromatic heterocyclic group optionally having a substituent. Examples of the divalent sulfur-containing aromatic heterocyclic group include a benzothiazole diyl group, a thienothiazole diyl group, and a thiazole diyl group, and a benzothiazole diyl group is preferable. The substituent in Ar¹, Ar², and Ar³ may be at least one selected from the group consisting of a halogen atom, a hydroxy group, a methyl group, and a methoxy group, and is preferably a fluorine atom, a chlorine atom, a hydroxy group, a methyl group, or a methoxy group, and more preferably a fluorine atom or a hydroxy group. The numbers of substituents in Ar¹, Ar², and Ar³ are each independently, for example, 0, 1, or 2, and preferably 0 or 1.

At least one of Ar¹ and Ar² has a fluorine atom as a substituent. That is, at least one of Ar¹ and Ar² may have a fluorine atom as a substituent, or when Ar² has a fluorine atom as a substituent and there are two Ar²s, at least one Ar² may have a fluorine atom as a substituent. The total number of fluorine atoms in Ar¹ and Ar² is, for example, 1 to 4, preferably 1 to 3, or 1 or 2. A substitution position of the fluorine atom in Ar¹ and Ar² may be, for example, a meta position with respect to the azo group. At least one of Ar¹ and Ar² may have a hydroxy group in addition to a fluorine atom. The fluorine atom and the hydroxy group may be substituted with one of Ar¹ and Ar², or may be substituted with each of Ar¹ and Ar². Since the fluorine atom and the hydroxy group have the same size and electronegativity, it is considered that the light resistance of the first compound can be similarly improved.

P represents a single bond or at least one group selected from the group consisting of —OC(═O)—, —C(═O)O—, —NHC(═O)—, —C(═O)NH—, —C≡C—, —CH═CH—, —CH═N—, —N═N—, and —N═CH—. P is preferably —OC(═O)—, —C(═O)O—, —NHC(═O)—, —C(═O)NH—, or —N═N—, more preferably —OC(═O)—, —NHC(═O)—, or —N═N—.

n represents 1 or 2. When n is 2, two Ar²s and two Ps may be the same or different to each other. That is, the two Ar²s may be the same or different to each other, and the two Ps may be the same or different to each other.

The first compound may have the maximum absorption wavelength (Amax), for example, in a wavelength range different from the maximum absorption wavelength of the second compound described later. The maximum absorption wavelength of the first compound may be, for example, 350 nm or more and 600 nm or less, and preferably 380 nm or more and 550 nm or less. The maximum absorption wavelength is measured at room temperature (for example, 25° C.) for a chloroform solution of the first compound. The maximum absorption wavelength of the first compound can be adjusted to a desired wavelength, for example, by appropriately selecting the skeleton structures of Ar¹, Ar², and Ar³, the substituents in Ar¹, Ar², and Ar³, n, R², and the like.

Specific examples of the first compound include compounds represented by the following formulas (1-1) to (1-70), but the present invention is not limited to these compounds. In the following specific examples, Et represents an ethyl group, and n-Bu represents a n-butyl group.

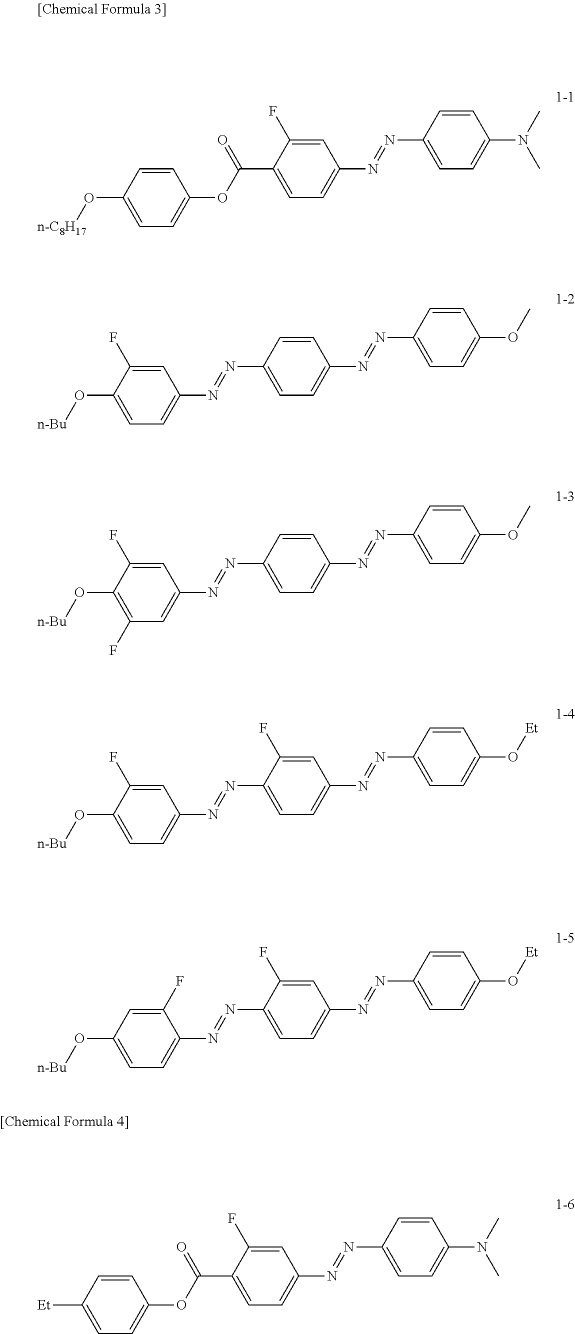

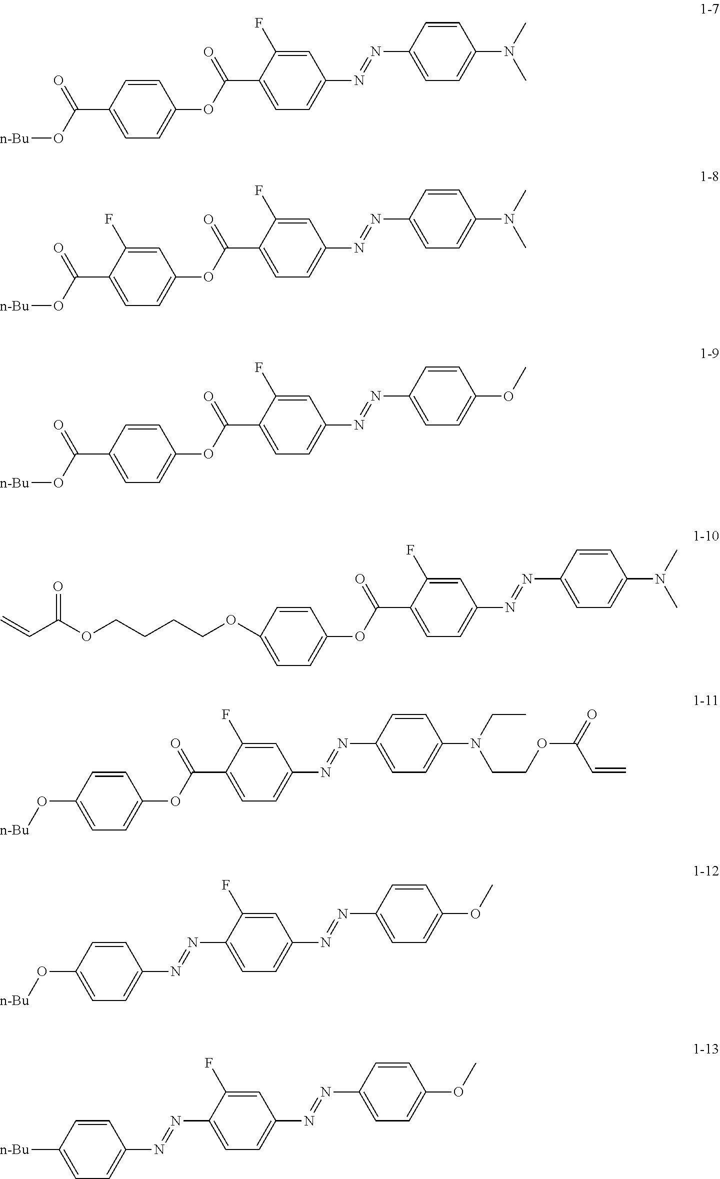

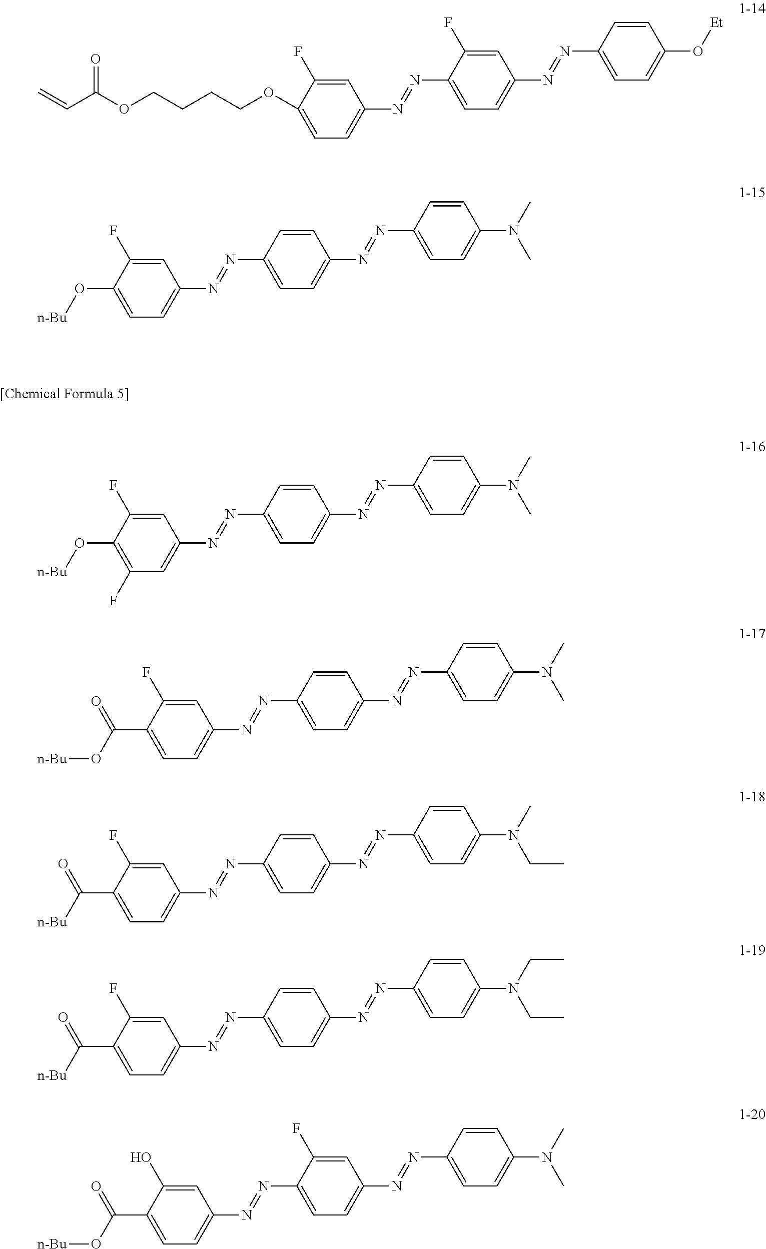

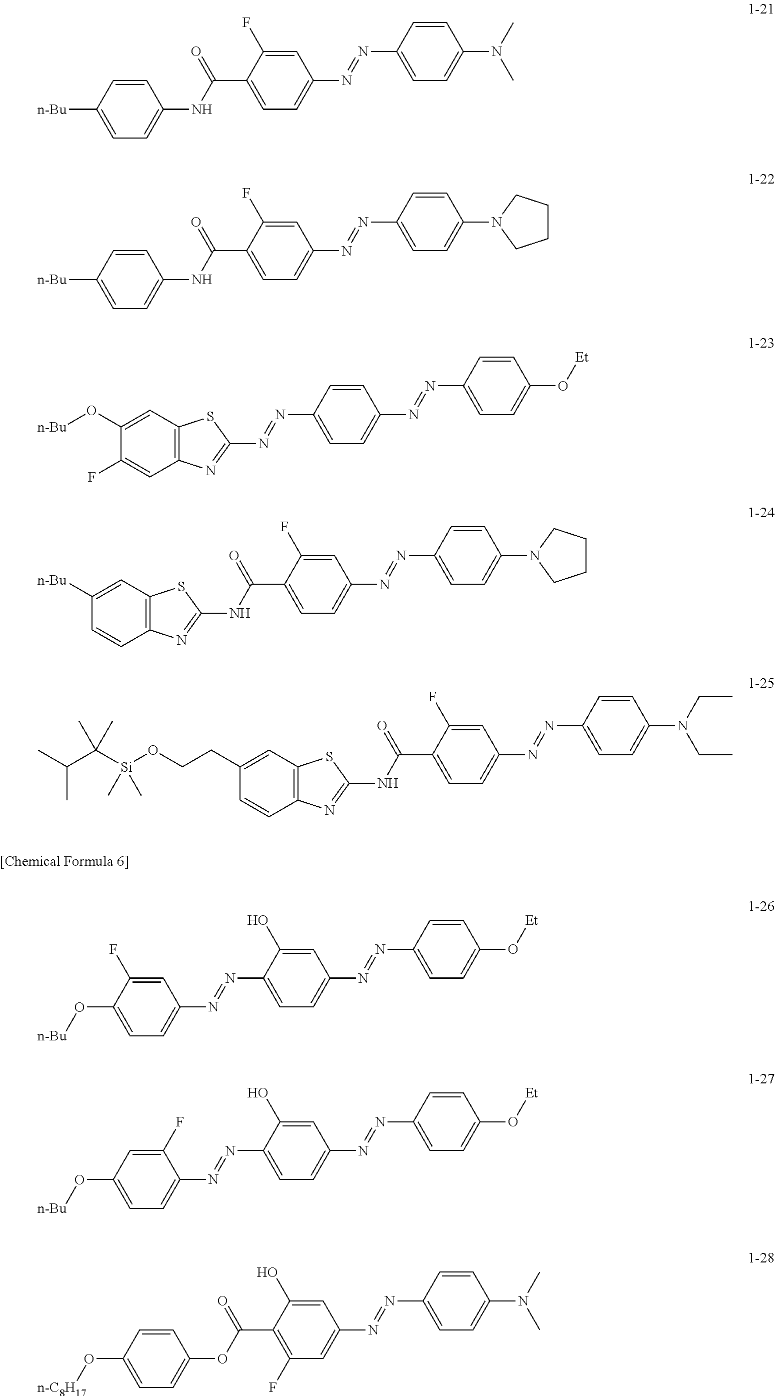

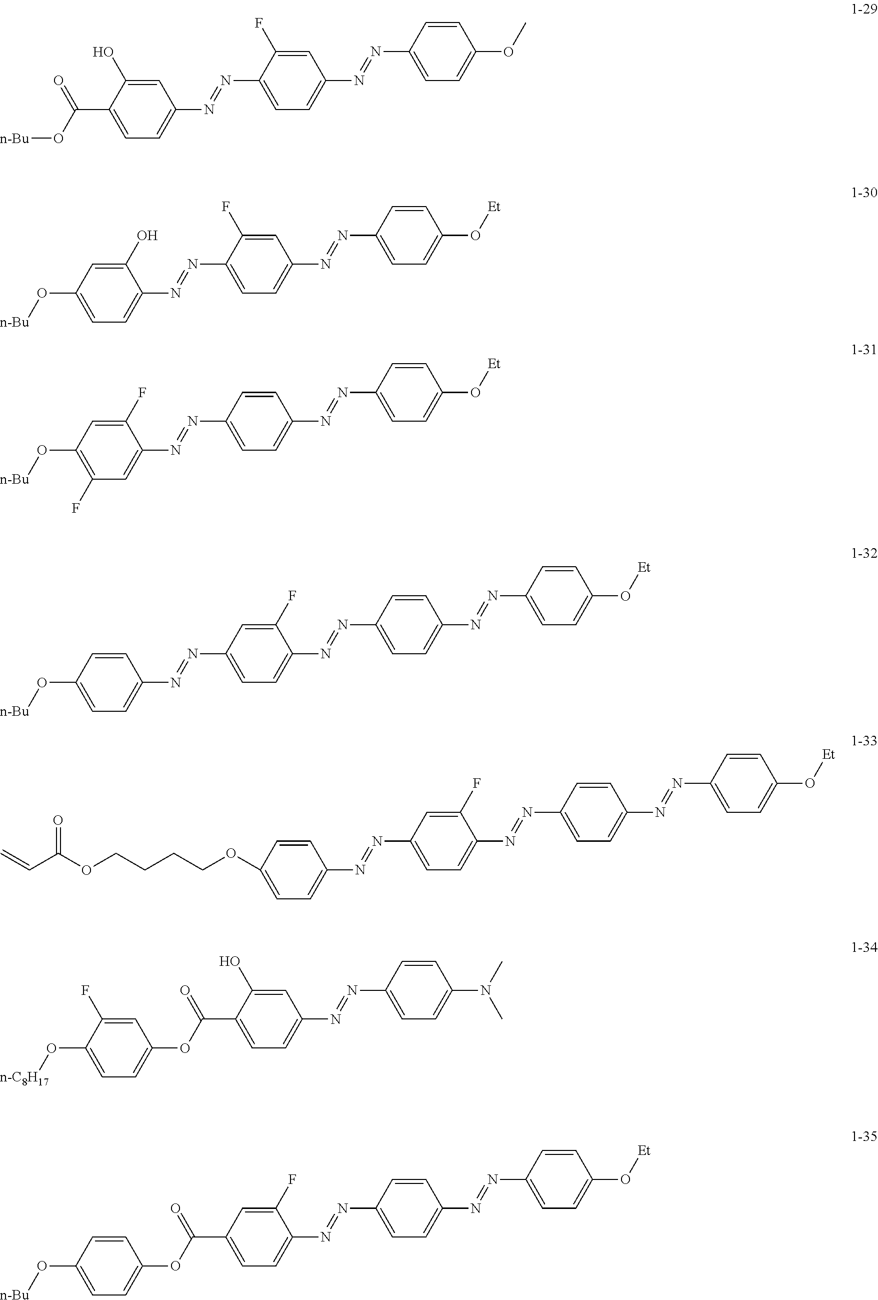

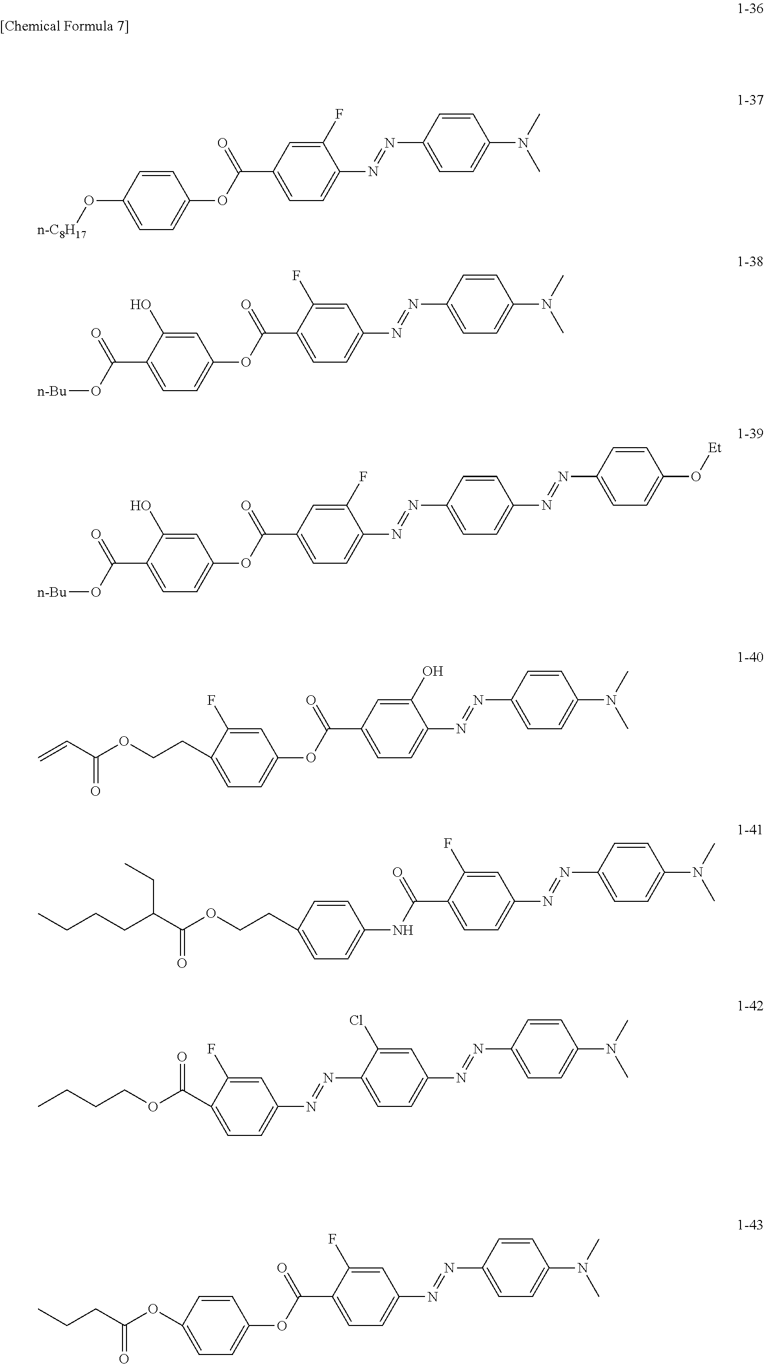

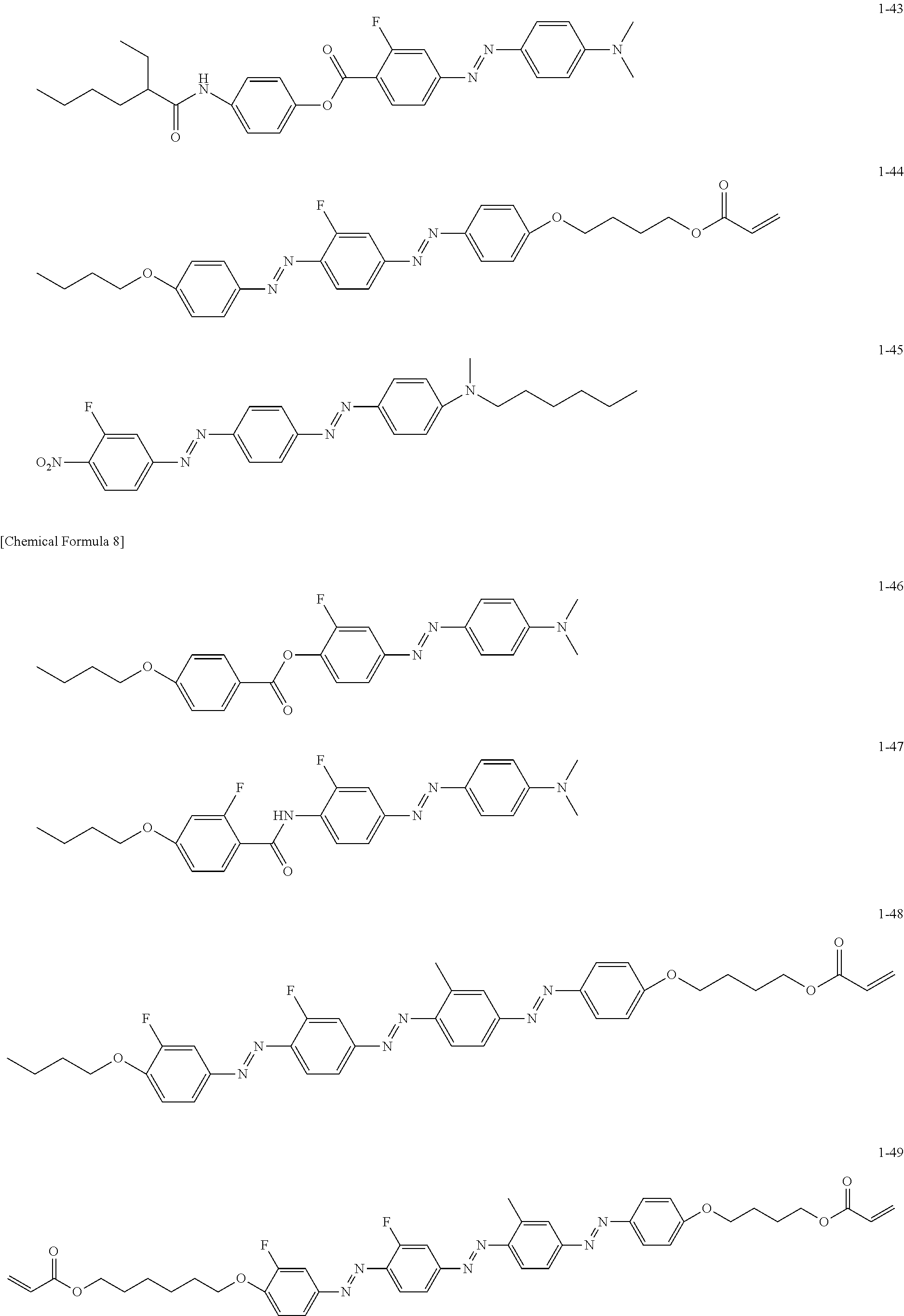

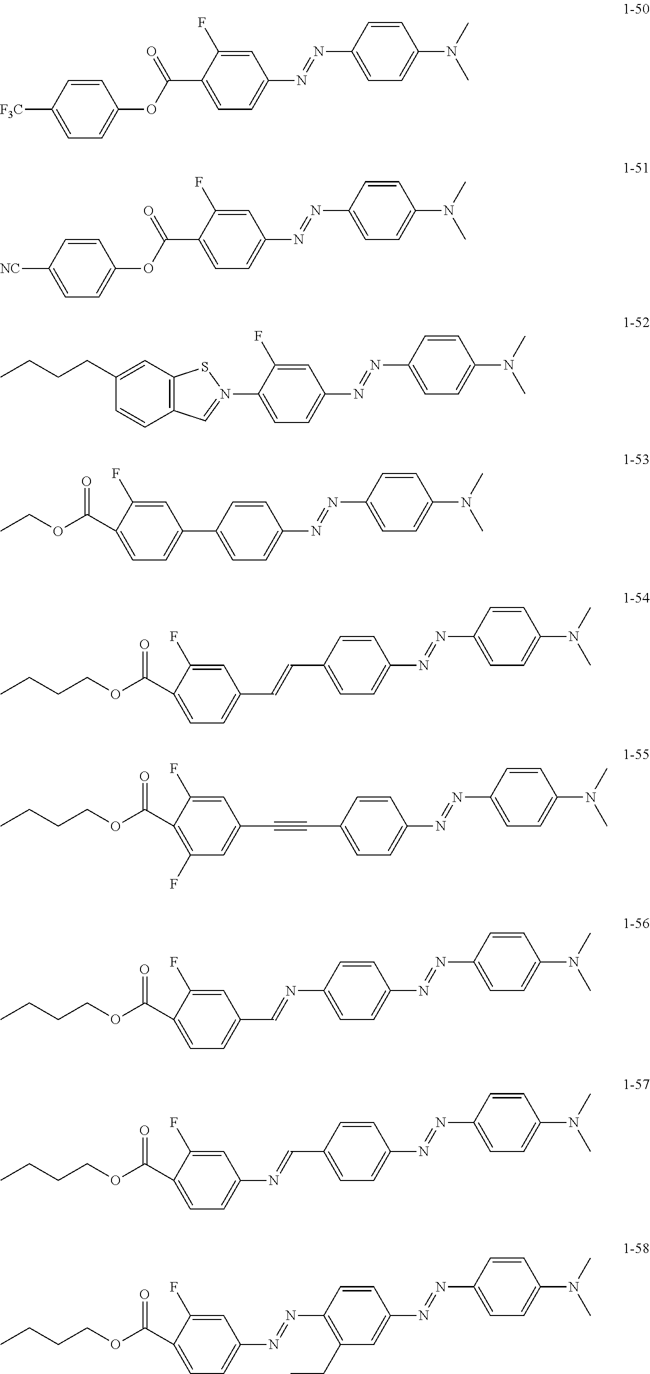

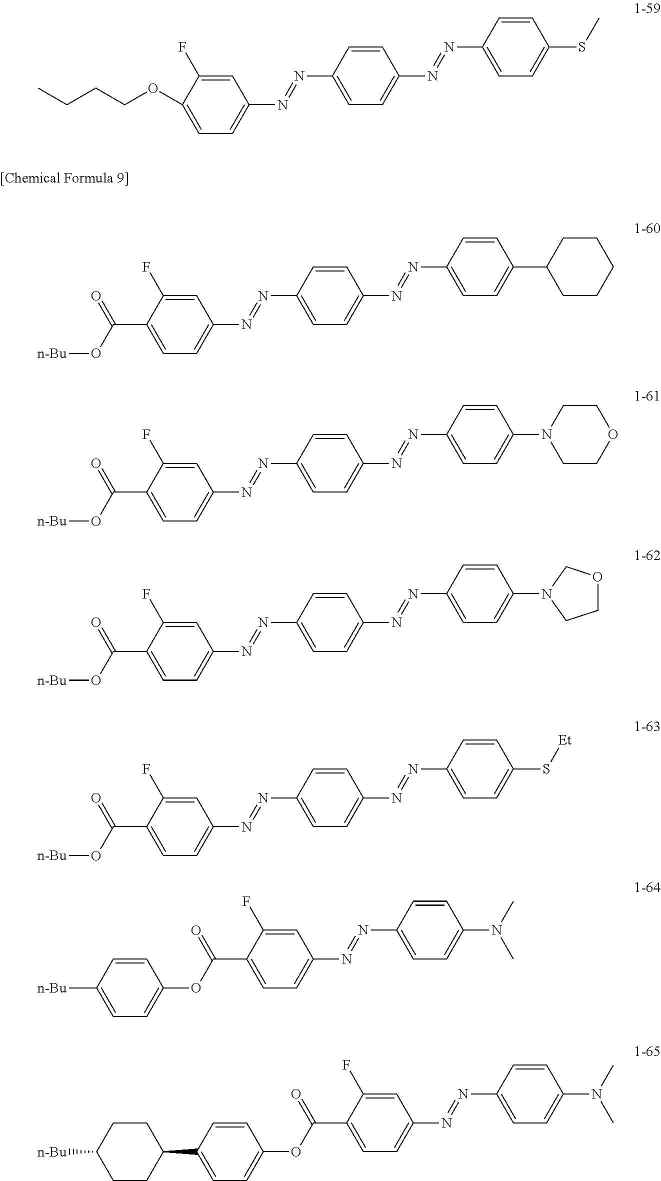

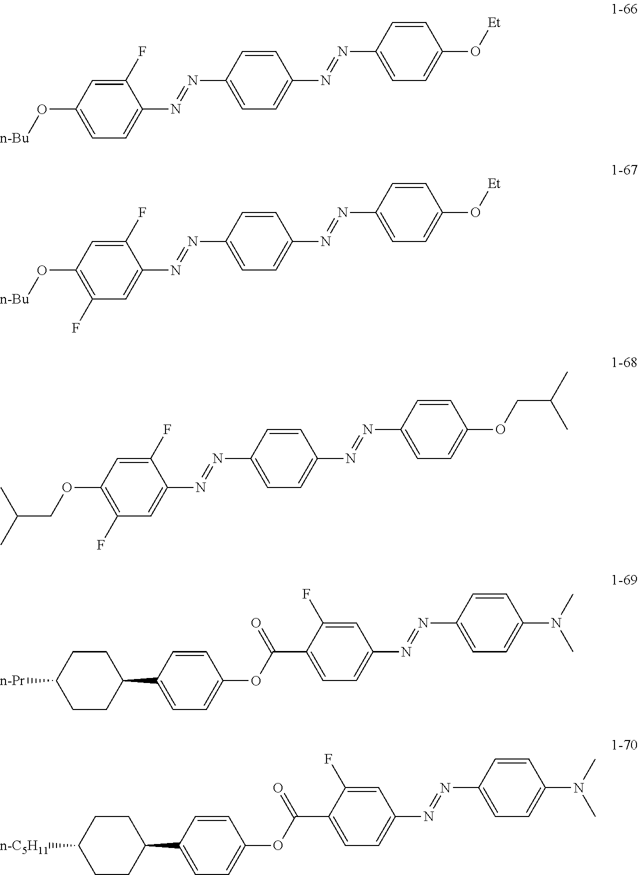

From the viewpoint of maintaining the dichroic ratio, the first compound is preferably at least one selected from the group consisting of the compounds represented by any of the formulas (1-1) to (1-51) and (1-60) to (1-70), and more preferably at least one selected from the group consisting of the compounds represented by any of the formulas (1-1) to (1-40) and (1-64) to (1-70).

### Second Compound

The composition contains at least one of the second compounds. The second compound has a structure represented by the formula (2), and has a maximum absorption wavelength in a wavelength range of 550 nm or more and 650 nm or less.

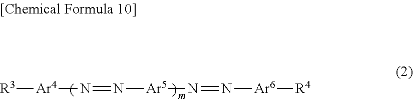

In the formula (2), R³ represents a substituent. Details of the substituent represented by R³ are the same as those of the substituent represented by R¹ in the formula (1). R⁴ represents one group selected from the group consisting of an alkylamino group, an alkoxy group and an alkylthio group, is preferably an alkylamino group, and is, for example, a dialkylamino group. R⁴ is more preferably a dimethylamino group, a diethylamino group, an ethylmethylamino group, a pyrrolidyl group, a piperidyl group, a morpholinyl group, or an oxazolidinyl group. At least one of the hydrogen atoms of the group represented by R⁴ may be substituted with a polymerizable group. When R⁴ has a polymerizable group, the number thereof is, for example, 1 or 2, and preferably 1.

Ar⁴, Ar⁵, and Ar⁶ each independently represent a 1,4-phenylene group optionally having a substituent, a naphthalenediyl group optionally having a substituent, or a divalent sulfur-containing aromatic heterocyclic group optionally having a substituent. Examples of the divalent sulfur-containing aromatic heterocyclic group include a thiazole diyl group, a benzothiazole diyl group, and a thienothiazole diyl group. At least one of Ar⁴, Ar⁵, and Ar⁶ preferably represents a divalent sulfur-containing aromatic heterocyclic group, and more preferably represents a thienothiazole diyl group. More preferably, Ar⁶ represents a thienothiazole diyl group.

The naphthalenediyl group in Ar⁴, Ar⁵, and Ar⁶ may be, for example, a naphthalene-1,4-diyl group. The thiazole diyl group may be a thiazole-2,4-diyl group or a thiazole-2,5-diyl group, the benzothiazole diyl group may be a benzothiazole-2,5-diyl group or a benzothiazole-2,6-diyl group, and the thienothiazole diyl group may be a thieno[2,3-d] thiazole-2,5-diyl group.

The substituent in Ar⁴, Ar⁵, and Ar⁶ may be at least one selected from the group consisting of a halogen atom, a hydroxy group, a methyl group, and a methoxy group, and is preferably a fluorine atom, a chlorine atom, a hydroxy group, a methyl group, or a methoxy group, and more preferably a fluorine atom or a hydroxy group. The numbers of substituents in Ar⁴, Ar⁵, and Ar⁶ are each independently, for example, 0, 1, or 2, and preferably 0 or 1.

m represents 1 or 2. When m is 2, two Ar⁵s may be the same or different to each other.

The second compound has the maximum absorption wavelength (Amax) in the wavelength range of 550 nm or more and 650 nm or less, but may have the maximum absorption wavelength (Amax) preferably in a wavelength range of 560 nm or more and 640 nm or less, and more preferably in a wavelength range of 570 nm or more and 630 nm or less. The maximum absorption wavelength is measured at room temperature (for example, 25° C.) for a chloroform solution of the second compound. The maximum absorption wavelength of the second compound can be adjusted to a desired wavelength, for example, by appropriately selecting the skeleton structures of Ar⁴, Ar⁵, and Ar⁶, the substituents in Ar⁴, Ar⁵, and Ar⁶, n, R⁴, and the like.

Specific examples of the second compound include compounds represented by the following formulas (2-1) to (2-42), but the present invention is not limited to these compounds.

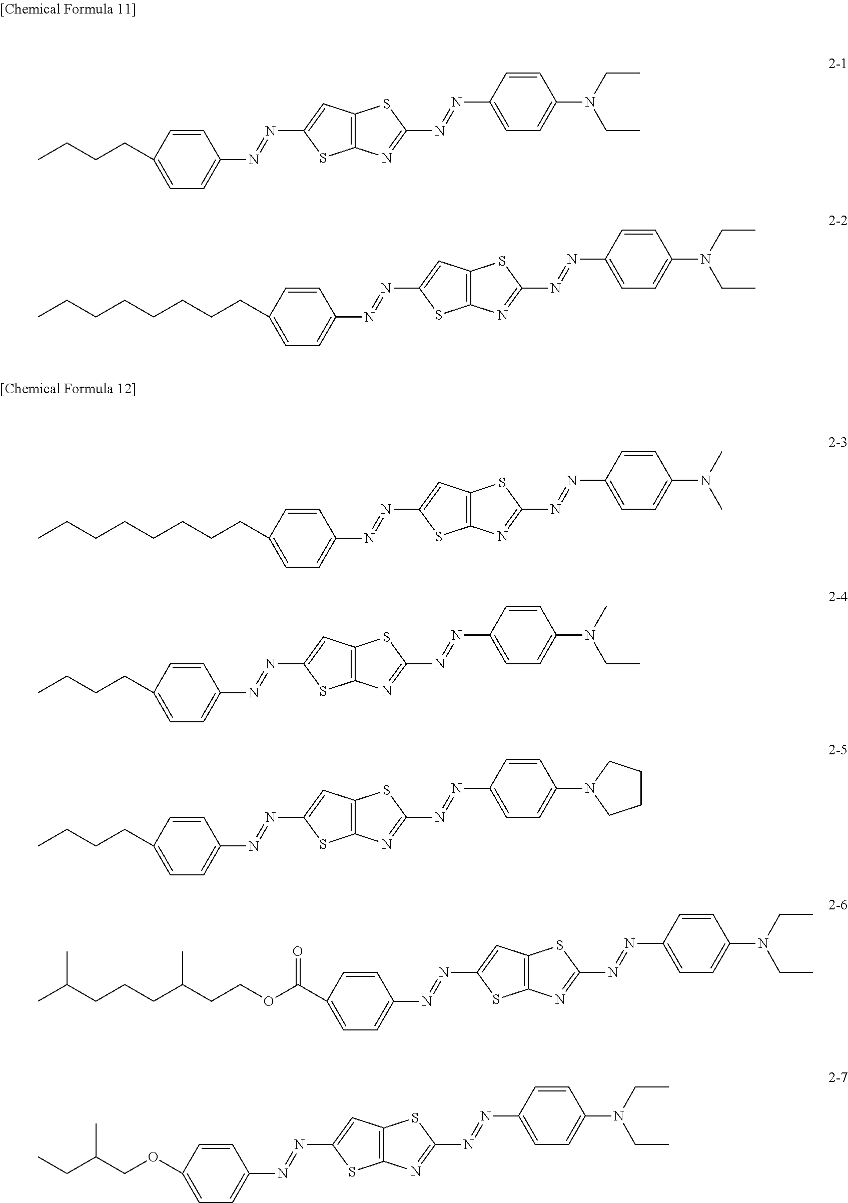

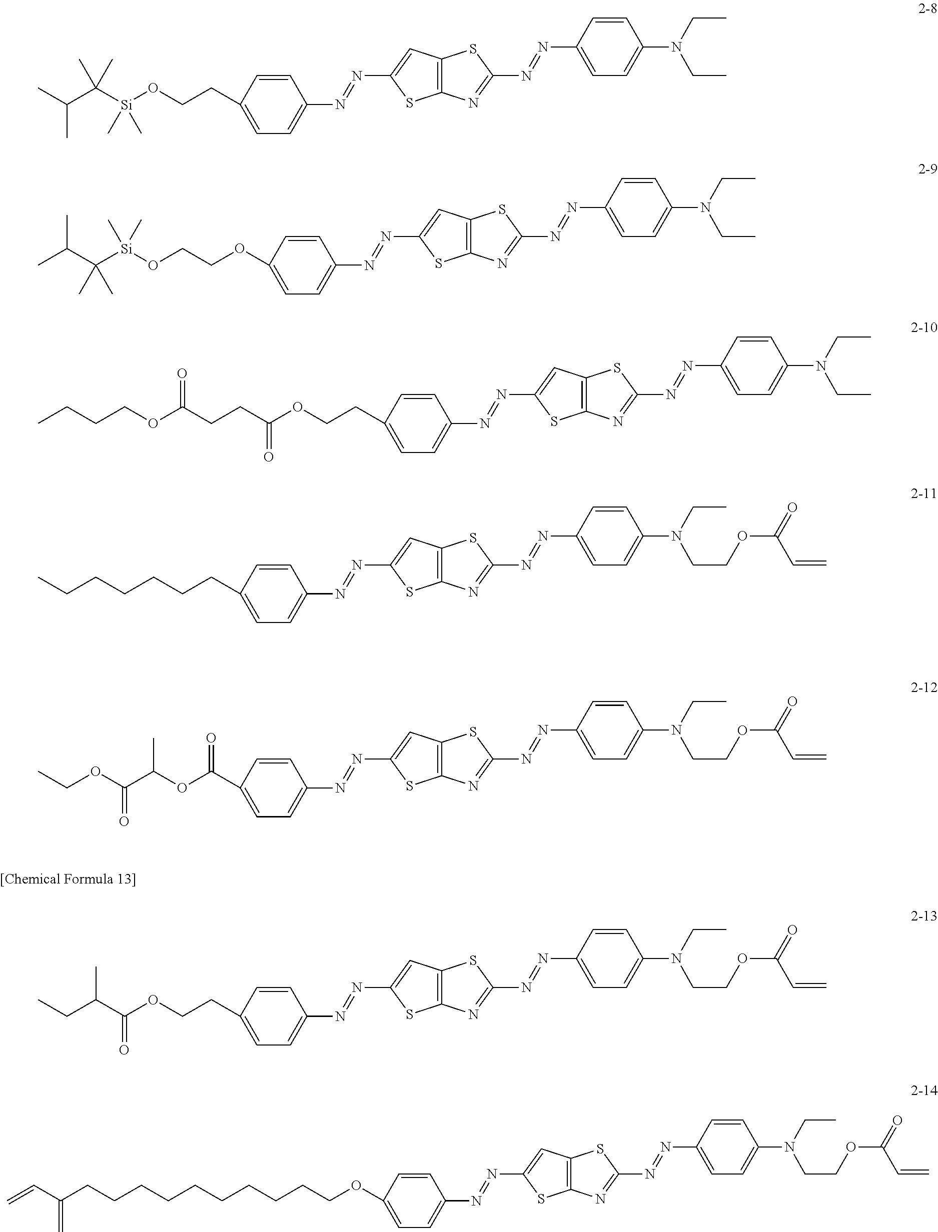

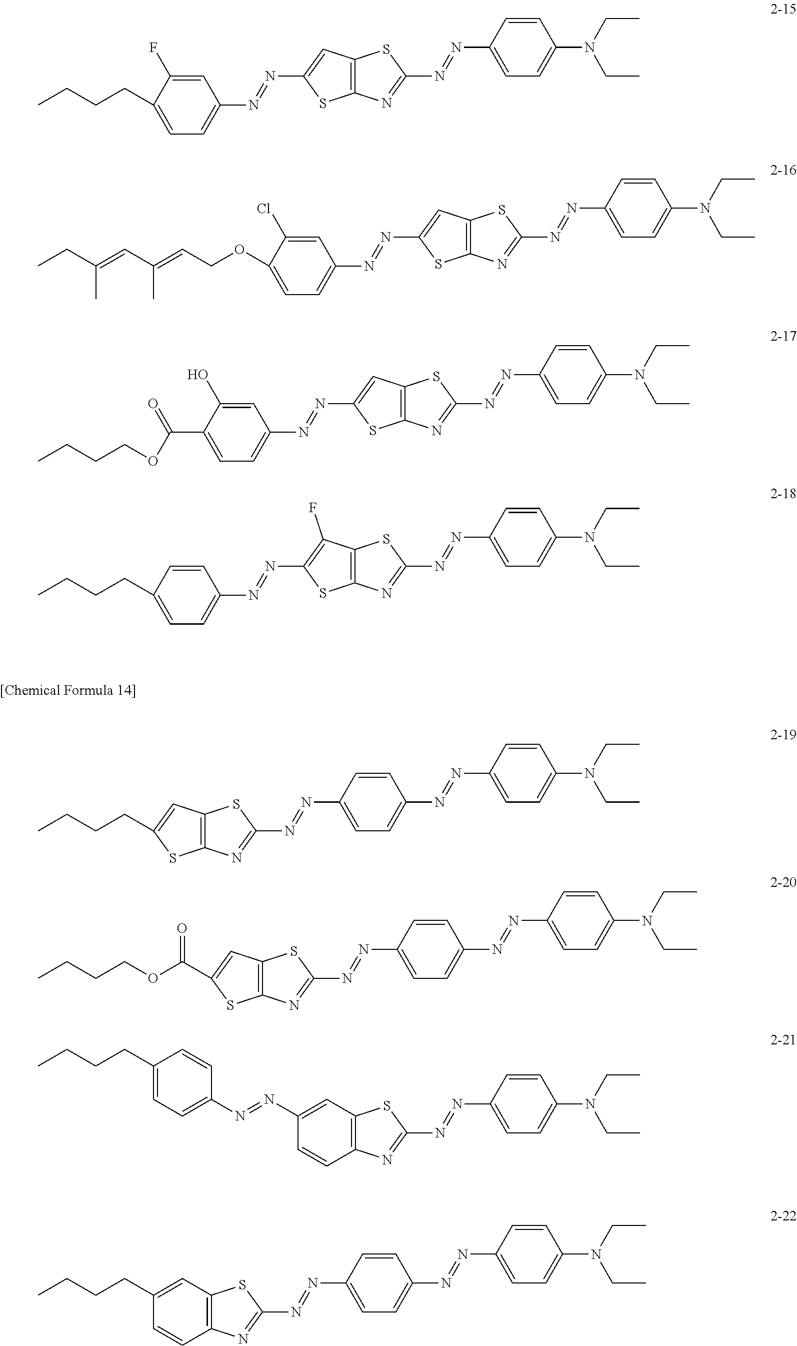

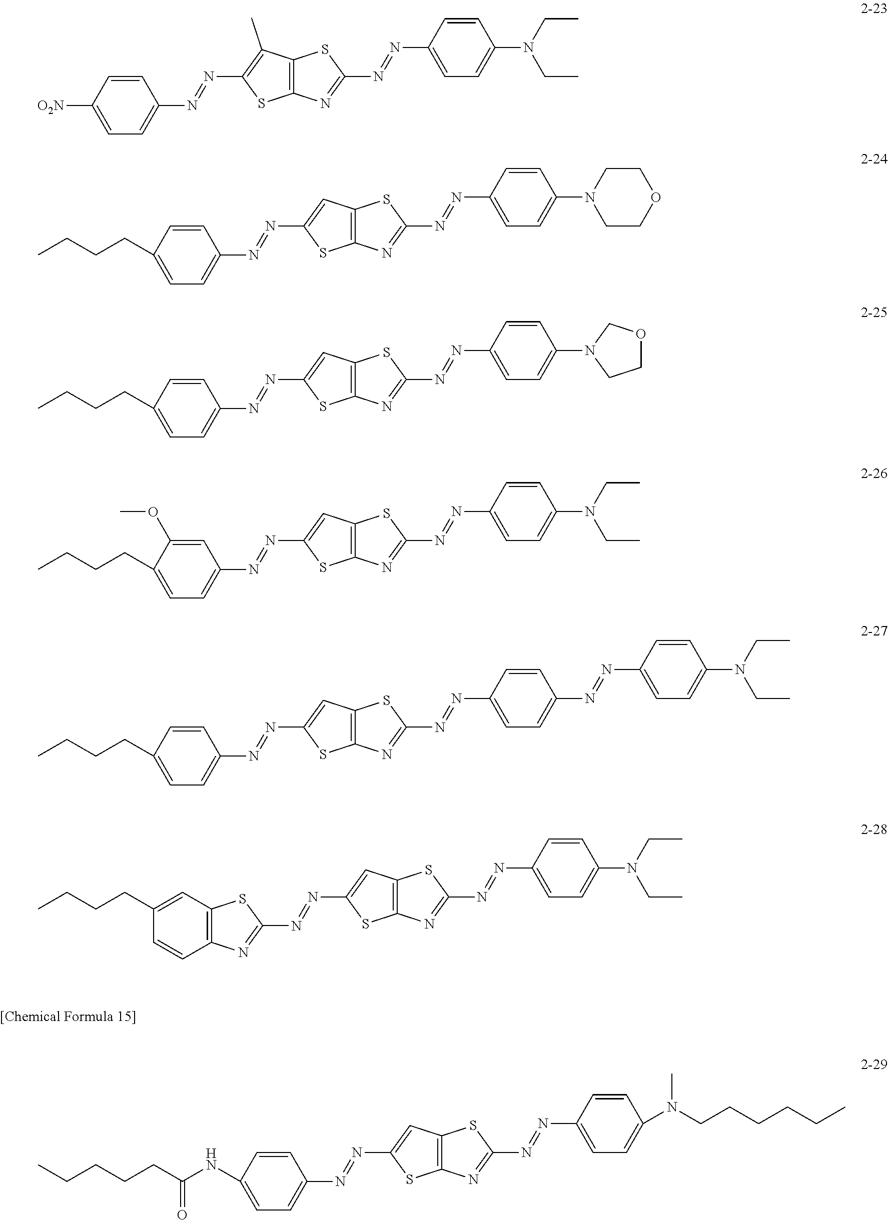

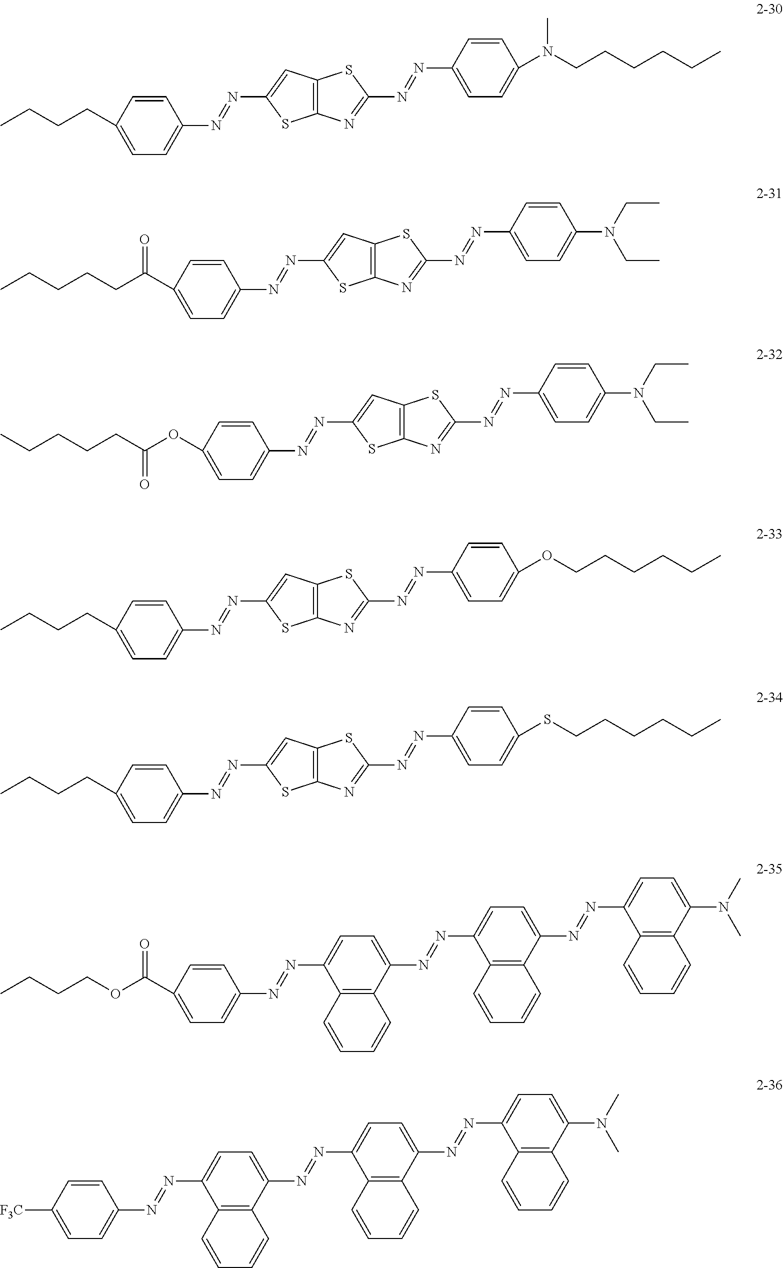

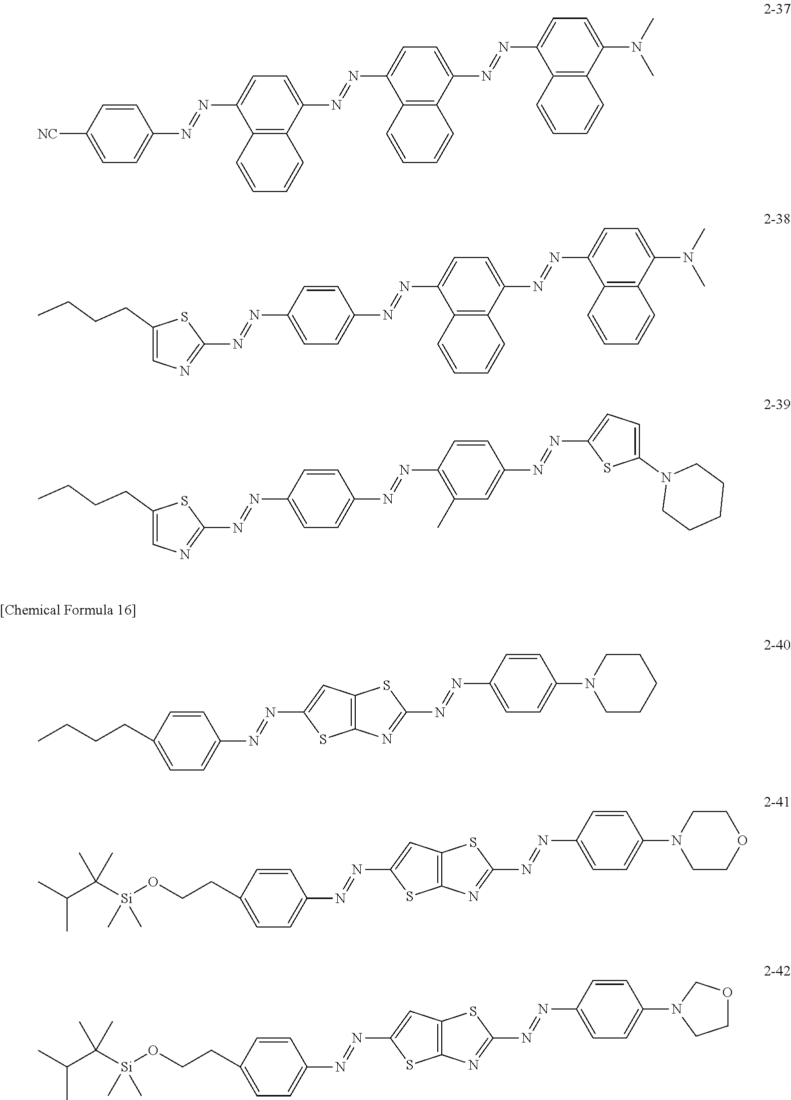

From the viewpoint of the dichroic ratio, the second compound is preferably at least one selected from the group consisting of the compounds represented by any of the formulas (2-1) to (2-32) and (2-40) to (2-42), and more preferably at least one selected from the group consisting of the compounds represented by any of the formulas (2-1) to (2-18).

The content of the first compound in the composition is, for example, preferably 50 parts by mass or less, more preferably in a range of 0.1 parts by mass or more and 10 parts by mass or less, and still more preferably in a range of 0.1 parts by mass or more and 5 parts by mass or less, based on 100 parts by mass of the solid content of the composition. Within the above range, the first compound can be sufficiently dispersed. As a result, it is possible to efficiently obtain a film including, as a forming material, a composition containing the first compound, in which the occurrence of defects is sufficiently suppressed. In the present specification, the solid content refers to a total amount of components obtained by removing a volatile component such as a solvent from the composition. The composition may contain only one type of the first compound, or may contain two or more types having different structures in combination. When the composition contains two or more types of the first compounds, the compounds may have different maximum absorption wavelengths from each other.

The content of the second compound in the composition is, for example, preferably 50 parts by mass or less, more preferably in a range of 0.1 parts by mass or more and 10 parts by mass or less, and still more preferably in a range of 0.1 parts by mass or more and 5 parts by mass or less, based on 100 parts by mass of the solid content of the composition. Within the above range, the first compound can be sufficiently dispersed. As a result, it is possible to efficiently obtain a film including, as a forming material, a composition containing the second compound, in which the occurrence of defects is sufficiently suppressed. The composition may contain only one type of the second compound, or may contain two or more types having different structures in combination. When the composition contains two or more types of the second compounds, the compounds may have different maximum absorption wavelengths from each other.

A content ratio of the first compound and the second compound in the composition may be, as a ratio of the content of the second compound to the content of the first compound, for example, 0.5 or more and 2.0 or less, and preferably 0.6 or more and 1.8 or less, or 0.7 or more and 1.5 or less.

### Process for Producing First Compound and Second Compound

The first compound and the second compound can be produced by appropriately applying a conventionally known synthesis method. Specifically, an azo structure (—N═N—) in the first compound and the second compound can be constructed, for example, by converting an aromatic amine compound having a primary amino group into a diazonium salt with sodium nitrite or the like and diazo-coupling the diazonium salt with an aromatic compound, with reference to the description of the production examples in paragraphs [0220] to [0268] of WO 2016/136561 A. An azo structure including a thiazole structure can be constructed, for example, with reference to the description of J. Mol. Struct., 2011, 987,158.

A compound in which R¹, R², R³, or R⁴ is an alkoxy group can be produced, for example, as a compound having a desired alkoxy group by applying an S_{N}2 substitution reaction to a precursor having a hydroxy group. For the S_{N}2 substitution reaction, conventionally known reaction conditions may be appropriately applied, and for example, the description of J. Am. Chem. Soc., 2008, 130, and 13079 may be referred to.

When the first compound or the second compound contains —OC(═O)— or C(═O)O—, for example, a precursor having a carboxy group and a precursor having a hydroxyl group are used, and the compound can be synthesized by applying a dehydration condensation reaction with reference to Jiang, L.; Lu, X.; Zhang, H.; Jiang, Y.; Ma, D. J. Org. Chem. 2009, 74 (3), 4542-4546., and the like. Specific examples thereof include conditions for condensation in a solvent in the presence of an esterified condensing agent.

When the first compound or the second compound contains NHC(═O)— or C(═O)NH—, for example, the compound can be synthesized by using a precursor having a carboxy group and a precursor having an amino group and applying the dehydration condensation reaction. Specific examples thereof include conditions for condensation in a solvent in the presence of an amidated condensing agent.

When the first compound or the second compound has a silyloxy group substituted with an aliphatic hydrocarbon group, the compound can be synthesized by using a precursor having a hydroxyl group and a halogenated silane substituted with an aliphatic hydrocarbon group and applying conditions of a general silylation reaction in the presence of a base. As conditions of the S_{N}2 substitution reaction, for example, J. Am. Chem. Soc., 1972, 94, 6190, and the like can be referred to.

The compound in which P in the first compound is —C≡C— can be synthesized, for example, by using a precursor having an ethynyl group (—C≡CH) and a precursor having a halogen atom and applying Sonogashira coupling using a Pd or Cu catalyst.

The compound in which P in the first compound is —C═C— can be synthesized, for example, by using a precursor having an ethenyl group (—C═CH) and a precursor having a halogen atom and applying a Heck reaction using a Pd catalyst and a phosphorus ligand.

A compound in which P in the first compound is —CH═N— or —N═CH— can be synthesized by subjecting a precursor having a formyl group and a precursor having an amino group to a general dehydration condensation reaction.

The reaction time in the process for producing the first compound or the second compound can also be determined by appropriately sampling a reaction mixture in the middle of the reaction and confirming a degree of disappearance of a raw material compound, a degree of generation of the first compound or the second compound, and the like by a known analysis means such as liquid chromatography or gas chromatography.

From the reaction mixture after the reaction, the first compound or the second compound can be extracted by a known method such as recrystallization, reprecipitation, extraction, and various types of chromatography, or by appropriately combining these operations.

The composition may further contain another dye compound other than the first compound and the second compound, for example, at least one of dichroic dyes. Examples of the other dye compound include azo dyes such as a monoazo dye, a bisazo dye, a trisazo dye, a tetrakis azo dye, and a stilbene azo dye, and at least one selected from the group consisting of these dyes is preferable. The composition may contain the other dye compound alone or in combination of two or more. For example, when the composition is used as a coating type polarizing plate material, the other dye compound contained in the composition preferably has the maximum absorption wavelength in a wavelength range different from those of the first compound and the second compound. For example, when used as the coating type polarizing plate material, the composition preferably contains three or more dichroic dyes including the first compound and the second compound in combination, and more preferably contains three or more azo dyes in combination. When the composition contains three or more dye compounds having different maximum absorption wavelengths in combination, for example, absorption can be obtained in the entire visible light region by a film formed from the composition.

When the composition contains another dye compound, the content thereof is preferably 50 parts by mass or less, more preferably 0.1 parts by mass or more and 10 parts by mass or less, and still more preferably 0.1 parts by mass or more and 5 parts by mass or less, based on 100 parts by mass of the solid content of the composition. Within the above range, other dye compounds can be sufficiently dispersed.

### Liquid Crystalline Compound

The composition contains, in addition to the first compound and the second compound, a liquid crystalline compound containing at least one of a polymerizable liquid crystal compound and a liquid crystalline polymer compound. The composition may contain only one or both of the polymerizable liquid crystal compound and the liquid crystalline polymer compound. The composition may contain two or more kinds of polymerizable liquid crystal compounds and two or more kinds of liquid crystalline polymer compounds. When the composition contains at least one of a polymerizable liquid crystal compound and a liquid crystalline polymer compound, it is possible to form a composition in which the first compound and the second compound are dispersed in the liquid crystalline compound.

The liquid crystalline polymer compound may constitute a thermotropic liquid crystal polymer or a lyotropic liquid crystal polymer. The liquid crystalline polymer compound preferably constitutes a thermotropic liquid crystal polymer from the viewpoint of enabling dense film thickness control.

The liquid crystal is classified into a smectic liquid crystal, a nematic liquid crystal, and a cholesteric liquid crystal according to a structure of molecular arrangement in a liquid crystal state. Among them, the smectic liquid crystal is preferably used in polarizing film applications. Therefore, the polymerizable liquid crystal compound is preferably a polymerizable smectic liquid crystal compound, and the liquid crystalline polymer compound is preferably a smectic liquid crystalline polymer compound.

By using a polymerizable liquid crystal compound exhibiting smectic liquid crystallinity and a polymer compound exhibiting smectic liquid crystallinity, a polarizing film having a high degree of orientation order can be formed. The liquid crystal state exhibited by the polymerizable liquid crystal compound and the liquid crystalline polymer compound is preferably a smectic phase (smectic liquid crystal state), and is more preferably a higher order smectic phase (higher order smectic liquid crystal state) from the viewpoint of being able to realize a higher degree of orientation order. Here, the higher order smectic phase means a smectic B phase, a smectic D phase, a smectic E phase, a smectic F phase, a smectic G phase, a smectic H phase, a smectic I phase, a smectic J phase, a smectic K phase, and a smectic L phase, and among these phases, the smectic B phase, the smectic F phase, and the smectic I phase are more preferable. In the polarizing film having a high degree of orientation order, a Bragg peak derived from a higher order structure such as a hexatic phase or a crystal phase in X-ray diffractometry is obtained. The Bragg peak means a peak derived from the periodic structure of molecular orientation. A periodic interval (order period) of a polarizing film obtained from the composition is preferably 0.3 nm or more and 0.6 nm or less. The polymerizable liquid crystal compound or the liquid crystalline polymer compound may be a polymerizable smectic liquid crystal compound or a smectic liquid crystalline polymer compound that exhibits the Bragg peak derived from a higher order structure in X-ray diffraction measurement.

### Polymerizable Liquid Crystal Compound

The polymerizable liquid crystal compound is a compound having at least one polymerizable group in the molecule and capable of exhibiting a liquid crystal phase by orientation. The polymerizable liquid crystal compound is preferably a compound capable of exhibiting the liquid crystal phase by being oriented alone. The polymerizable group means a functional group capable of being involved in polymerization reaction, and is preferably a radical polymerizable group.

The polymerizable liquid crystal compound is not particularly limited as long as it is a liquid crystal compound having at least one polymerizable group and preferably exhibiting smectic liquid crystallinity, and a known polymerizable liquid crystal compound can be used. Specific examples of the polymerizable liquid crystal compound preferably include a compound represented by the following formula (A) (hereinafter also referred to as a “polymerizable liquid crystal compound (A)”).

U¹-V¹-W¹-(X¹-Y¹)ₖ-X²-Y²-X³-W²-V²-U² (A)

In the formula (A), k is an integer of 1 to 3. X¹, X², and X³ each independently represent a divalent aromatic group or a divalent alicyclic hydrocarbon group. When k is 2 or 3, a plurality of X¹s may be the same as or different to each other. At least three selected from the group consisting of X¹, X², and X³ represent a divalent hydrocarbon six-membered ring group. Y¹, Y², W¹, and W² each independently represent a single bond or a divalent linking group. When k is 2 or 3, Y¹s may be the same as or different to each other. V¹ and V² each independently represent an alkanediyl group having 1 to 20 carbon atoms optionally having a substituent. At least one of —CH₂-constituting the alkanediyl group may be substituted with —O—, —CO—, —S—, or —NH—. U¹ and U² each independently represent a polymerizable group or a hydrogen atom, and at least one of them represents a polymerizable group.

Examples of the divalent aromatic group in X¹, X², and X³ include a 1,4-phenylene group and a 1,4-naphthylene group (naphthalene-1,4-diyl group). Examples of the divalent alicyclic hydrocarbon group include a cyclohexane-1,4-diyl group. At least one of the divalent aromatic group and the divalent alicyclic hydrocarbon group in X¹, X², and X³ may have a substituent. Examples of the substituent include alkyl groups having 1 to 4 carbon atoms such as a methyl group, an ethyl group, and an n-butyl group, a cyano group, and a halogen atom. At least one of —CH₂— constituting the divalent alicyclic hydrocarbon group may be substituted with —O—, —S—, or —NR—. Here, R represents an alkyl group having 1 to 6 carbon atoms or a phenyl group.

Examples of the divalent hydrocarbon six-membered ring group in X¹, X², and X³ include a 1,4-phenylene group optionally having a substituent, and a cyclohexane-1,4-diyl group optionally having a substituent.

The divalent aromatic group in X¹, X², and X³ is preferably a 1,4-phenylene group optionally having a substituent, and more preferably an unsubstituted 1,4-phenylene group. The divalent alicyclic hydrocarbon group is preferably a cyclohexane-1,4-diyl group optionally having a substituent, more preferably a trans-cyclohexane-1,4-diyl group optionally having a substituent, and still more preferably a non-substituted trans-cyclohexane-1,4-diyl group.

Y¹ and Y² each independently represent a single bond or a divalent linking group. The divalent linking group is, for example, at least one selected from the group consisting of —CH₂CH₂—, —CH₂O—, —(C═O)O—, —O(C═O)O—, —N═N—, —CR^{a}═CR^{b}—, —C≡C—, and —CR^{a}═N—. Here, R^{a} and R^{b} each independently represent a hydrogen atom or an alkyl group having 1 to 4 carbon atoms. Y¹ is preferably —CH₂CH₂—, —(C═O)O—, or a single bond. Y² is preferably —CH₂CH₂— or —CH₂O—.

W¹ and W² each independently represent a single bond or a divalent linking group. The divalent linking group is, for example, at least one selected from the group consisting of —O—, —S—, —(C═O)O—, and —O(C═O)O—. W¹ and W² are each independently preferably a single bond or —O—.

V¹ and V² each independently represent an alkanediyl group having 1 to 20 carbon atoms optionally having a substituent. At least one of —CH₂— constituting the alkanediyl group may be substituted with —O—, —CO—, —S—, or —NH—.

Examples of the alkanediyl group represented by V¹ and V² include a methylene group, an ethylene group, a propane-1,3-diyl group, a butane-1,3-diyl group, a butane-1,4-diyl group, a pentane-1,5-diyl group, a hexane-1,6-diyl group, a heptane-1,7-diyl group, an octane-1,8-diyl group, a decane-1,10-diyl group, a tetradecane-1,1-diyl group, and an eicosane-1,20-diyl group. Each of V¹ and V² is preferably an alkanediyl group having 2 to 12 carbon atoms, and more preferably an alkanediyl group having 6 to 12 carbon atoms.

Examples of the substituent group optionally included in the optionally substituted alkanediyl group having 1 to 20 carbon atoms include a cyano group and a halogen atom. The alkanediyl group is preferably an unsubstituted alkanediyl group, and more preferably an unsubstituted and linear alkanediyl group.

U¹ and U² each independently represent a polymerizable group or a hydrogen atom, and at least one of them represents a polymerizable group. U¹ and U² are preferably polymerizable groups. Both of U¹ and U² are preferably polymerizable groups, and preferably radically polymerizable groups. The polymerizable group represented by U¹ and the polymerizable group represented by U² may be different from each other, but are preferably the same type of group. Examples of the polymerizable group in U¹ and U² include the same polymerizable groups as exemplified above as the polymerizable group of the polymerizable liquid crystal compound. Among them, the polymerizable group represented by U¹ and U² is preferably at least one selected from the group consisting of a vinyloxy group, an acryloyloxy group, a methacryloyloxy group, an oxiranyl group, and an oxetanyl group, and more preferably an acryloyloxy group.

Specific examples of the polymerizable liquid crystal compound (A) include compounds represented by the following formulas (A-1) to (A-17). When the polymerizable liquid crystal compound (A) has a cyclohexane-1,4-diyl group, the cyclohexane-1,4-diyl group is preferably of a trans type.

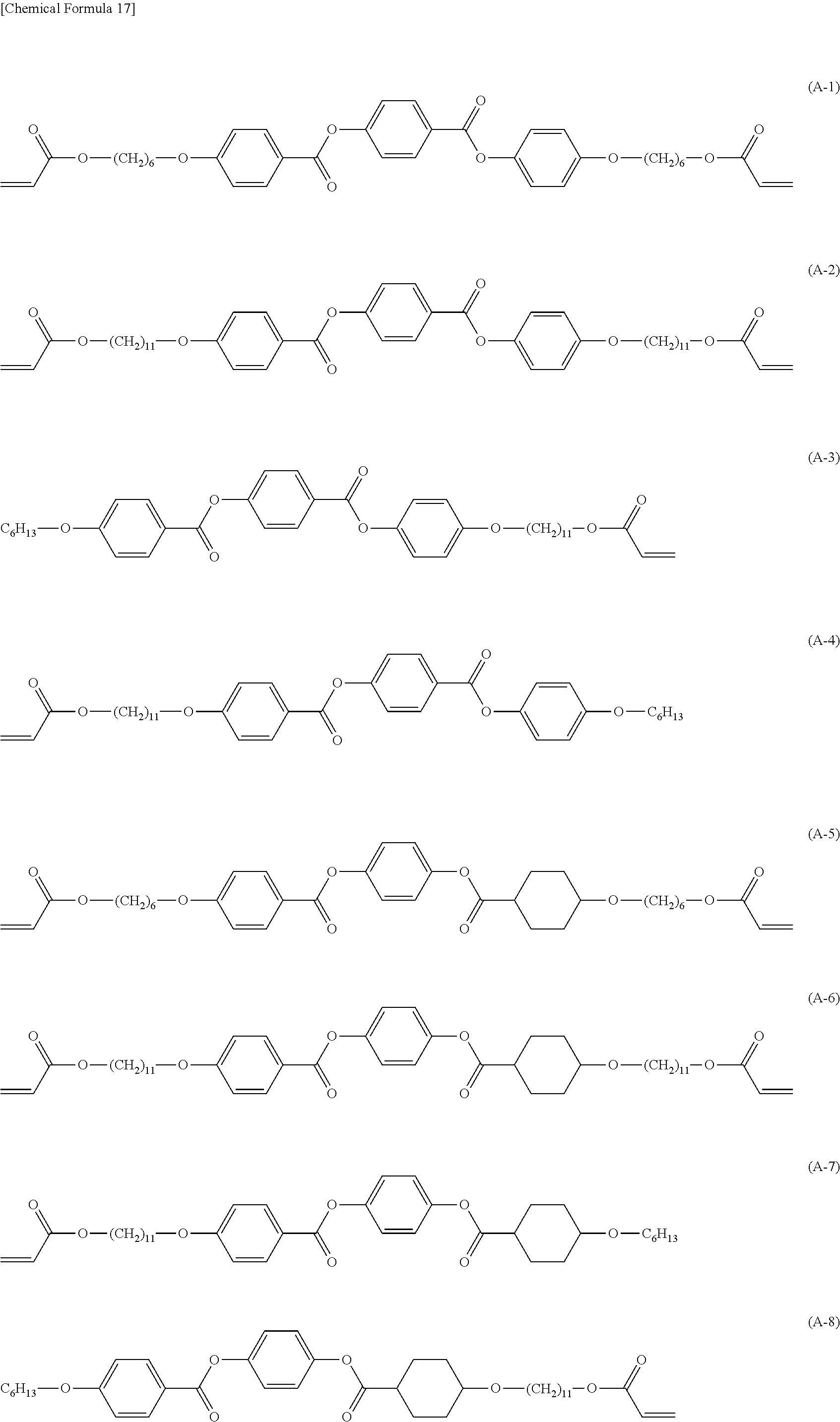

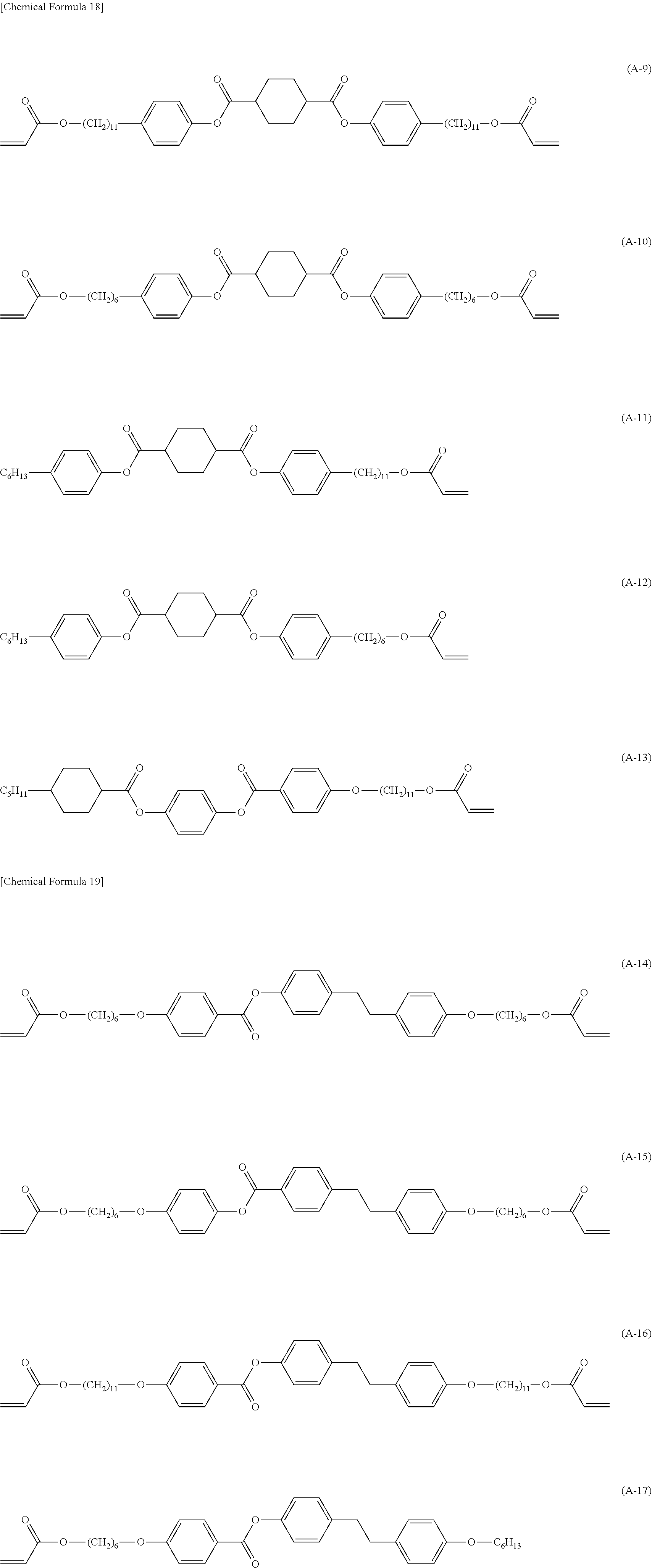

Among them, the polymerizable liquid crystal compound (A) is preferably at least one selected from the group consisting of compounds represented by any of the formula (A-2), formula (A-3), formula (A-4), formula (A-5), formula (A-6), formula (A-7), formula (A-8), formula (A-13), formula (A-14), formula (A-15), formula (A-16), and formula (A-17). As the polymerizable liquid crystal compound (A), one type may be used alone, or two or more types may be used in combination.

The polymerizable liquid crystal compound (A) can be produced by, for example, a method described in conventionally known documents such as Lub et al. Recl. Trav. Chim. Pays-Bas, 115, 321-328 (1996) and Japanese Patent No. 4719156.

### Liquid Crystalline Polymer Compound

The liquid crystalline polymer compound may be a compound obtained by polymerizing the polymerizable liquid crystal compound (hereinafter, also referred to as the polymer of the polymerizable liquid crystal compound), or may be another liquid crystalline polymer compound, and is preferably a polymer of the polymerizable liquid crystal compound.

As the polymer of the polymerizable liquid crystal compound, two or more kinds of the polymerizable liquid crystal compounds may be used as raw material monomers. The polymer of the polymerizable liquid crystal compound may contain another monomer other than the polymerizable liquid crystal compound as a raw material monomer.

A content ratio of the polymerizable liquid crystal compound in the polymer of the polymerizable liquid crystal compound is usually 1 mol % or more and 100 mol % or less based on a total amount of the constitutional units derived from the polymerizable liquid crystal compound constituting the polymer of the polymerizable liquid crystal compound, and is preferably 30 mol % or more and 100 mol % or less, more preferably 50 mol % or more and 100 mol % or less, and still more preferably 80 mol % or more and 100 mol % or less from the viewpoint of enhancing the orientation of the polymer of the polymerizable liquid crystal compound.

Examples of the other liquid crystalline polymer compound include a polymer compound having a liquid crystalline group. Examples of the polymer compound serving as the parent skeletal structure include polyolefins such as polyethylene and polypropylene; cyclic olefin resins such as norbornene polymers; polyalkylene ether, polyvinyl alcohol; polymethacrylic acid ester; and polyacrylic acid ester, and these polymer compounds have a liquid crystalline group. Among them, a polymethacrylic acid ester and a polyacrylic acid ester having a liquid crystalline group are preferable.

The other liquid crystalline polymer compound may contain two or more kinds of liquid crystalline groups. The liquid crystalline group may be contained in the main chain of the polymer compound serving as the parent skeletal structure, may be contained in the side chain of the polymer compound serving as the parent skeletal structure, or may be contained in both the main chain and the side chain of the polymer compound serving as the parent skeletal structure. Examples of the liquid crystalline group include a group formed by removing one hydrogen atom from a compound having at least two hydrocarbon six-membered ring structures, and a group formed by removing two hydrogen atoms from the compound.

A content ratio of the liquid crystalline group in the other liquid crystalline polymer compound is usually 1 mol % or more and 100 mol % or less based on a total amount of the constituent units constituting the polymer compound serving as the parent skeletal structure of the other liquid crystalline polymer compound, and is preferably 30 mol % or more and 100 mol % or less, more preferably 50 mol % or more and 100 mol % or less, and still more preferably 80 mol % or more and 100 mol % or less from the viewpoint of enhancing the orientation of the other liquid crystalline polymer compound.

When two or more kinds of polymerizable liquid crystal compounds are combined in the composition, it is preferable that at least one of them is the polymerizable liquid crystal compound (A), and it is more preferable that two or more of them are the polymerizable liquid crystal compound (A). By combining two or more kinds of polymerizable liquid crystal compounds, the liquid crystal phase may be temporarily retained even at a temperature equal to or lower than a liquid-crystal phase transition temperature. The content of the polymerizable liquid crystal compound (A) contained in the composition is preferably 40% by mass or more, and more preferably 60% by mass or more in total based on a total mass of all the polymerizable liquid crystal compounds in the composition, and all the polymerizable liquid crystal compounds may be the polymerizable liquid crystal compounds (A). When the content of the polymerizable liquid crystal compound (A) is within the above range, the polymerizable liquid crystal compounds are likely to be aligned with a high degree of orientation order, and the first compound and the second compound are oriented following the degree of orientation order, whereby a polarizing film having excellent polarizing performance can be obtained.

From the viewpoint of enhancing the orientation of the polymerizable liquid crystal compound and the liquid crystalline polymer compound, a total content ratio of the polymerizable liquid crystal compound and the liquid crystalline polymer compound in the composition is, for example, 50 parts by mass or more, preferably 70 parts by mass or more and 99.9 parts by mass or less, more preferably 70 parts by mass or more and 99.5 parts by mass or less, still more preferably 80 parts by mass or more and 99 parts by mass or less, particularly preferably 80 parts by mass or more and 94 parts by mass or less, and even more preferably 80 parts by mass or more and 90 parts by mass or less, based on 100 parts by mass of the solid content of the composition.

A total content of the first compound and the second compound in the composition is usually 0.1 parts by mass or more and 50 parts by mass or less, preferably 0.1 parts by mass or more and 20 parts by mass or less, more preferably 0.1 parts by mass or more and 10 parts by mass or less, and still more preferably 0.1 parts by mass or more and 5 parts by mass or less, based on 100 parts by mass of a total amount of the polymerizable liquid crystal compound and the liquid crystalline polymer compound. When the total content of the first compound and the second compound with respect to the total amount of the polymerizable liquid crystal compound and the liquid crystalline polymer compound is 50 parts by mass or less, there is a tendency that it is possible to obtain a polarizing film having little disturbance of the orientation of the polymerizable liquid crystal compound, the liquid crystalline polymer compound, the first compound, and the second compound and having a high degree of orientation order.

### Polymer Compound

The composition may further contain a polymer compound in addition to the first compound, the second compound, and the polymerizable liquid crystalline compound. When the composition contains the polymer compound, the first compound and the second compound may be easily dispersed in the composition. The polymer compound that can be contained in the composition is not particularly limited as long as the first compound and the second compound can be dispersed. From the viewpoint of easily uniformly dispersing the first compound and the second compound, an acrylic polymer such as polymethyl methacrylate (PMMA) is preferable. The polymer compound may be a polymer compound obtained by polymerizing the above-described polymerizable liquid crystal compound. A polystyrene equivalent weight average molecular weight of the polymer compound is, for example, 10,000 or more and 200,000 or less, and preferably 20,000 or more and 150,000 or less.

When the composition contains a polymer compound, the content thereof can be appropriately selected according to the purpose and the like. The content of the polymer compound is preferably 10 parts by mass or less, more preferably 5.0 parts by mass or less, and still more preferably 3.0 parts by mass or less, based on 100 parts by mass of the solid content of the composition.

The composition preferably further contains a liquid medium such as a solvent and a polymerization initiator, and may further contain a photosensitizer, a polymerization inhibitor, a leveling agent, and the like as necessary.

### Solvent

The solvent is preferably a solvent that can completely dissolve the first compound, the second compound, the polymerizable liquid crystal compound, the liquid crystalline polymer compound, and the polymer compound. The solvent is preferably inert to the polymerization reaction of the polymerizable liquid crystal compound.

Examples of the solvent include an alcohol solvent, an ester solvent, a ketone solvent, an aliphatic hydrocarbon solvent, an aromatic hydrocarbon solvent, a nitrile solvent, an ether solvent, and a chlorine-containing solvent. These solvents may be used alone, or two or more types of them may be used in combination.

When the composition contains a solvent, the content ratio of the solvent is preferably 50% by mass or more and 98% by mass or less to the total amount of the composition. In other words, the content ratio of the solid content in the composition is preferably 2% by mass or more and 50% by mass or less. If the amount of the solid content is 50% by mass or less, the viscosity of the composition is lowered, so that the thickness of a film obtained from the composition, for example, a film is made approximately uniform, and thus the film tends to be hardly uneven. A content ratio of the solid content can be determined in consideration of the thickness of a film to be produced.

### Polymerization Initiator

The polymerization initiator is a compound which can cause polymerization reaction of a polymerizable liquid crystal compound. The polymerization initiator is preferably a photopolymerization initiator in that the polymerization reaction can be initiated under lower temperature conditions. Specifically, a photopolymerization initiator capable of generating an active radical or an acid by light action can be mentioned, and in particular, a photopolymerization initiator that generates a radical by the light action is preferable.

Examples of the polymerization initiator include a benzoin compound, a benzophenone compound, an alkylphenone compound, an acylphosphine oxide compound, a triazine compound, an iodonium salt, and a sulfonium salt. The polymerization initiator can be appropriately selected from known polymerization initiators according to the purpose and the like. The polymerization initiator can be used alone or in combination of two or more.

When the composition contains the polymerization initiator, the content thereof may be appropriately determined according to the type and amount of the polymerizable liquid crystal compound contained in the composition. The content of the polymerization initiator is, for example, 0.001 parts by mass or more, 0.01 parts by mass or more, 0.1 parts by mass or more, or 0.5 parts by mass or more, and is, for example, 30% by mass or less, 10% by mass or less, or 8% by mass or less, based on 100 parts by mass of the polymerizable liquid crystal compound. The content of the polymerization initiator is preferably 0.001 parts by mass or more and 30 parts by mass or less, more preferably 0.01 parts by mass or more and 10 parts by mass or less, and still more preferably 0.1 parts by mass or more and 8 parts by mass or less, based on 100 parts by mass of the polymerizable liquid crystal compound. When the content of the polymerization initiator is within the above range, polymerization can be performed without disturbing the orientation of the polymerizable liquid crystal compound.

### Photosensitizer

When the composition contains a photopolymerization initiator, the composition preferably may contain at least one photosensitizer. When the composition contains a polymerization initiator and a photosensitizer, the polymerization reaction of the polymerizable liquid crystal compound tends to be further promoted. Examples of the photosensitizer include xanthone compounds such as xanthone and thioxanthone; anthracene compounds such as anthracene and alkoxy group-substituted anthracene; and phenothiazine and rubrene. The photosensitizers can be used alone or in combination of two or more.

When the composition contains the photosensitizer, the content of the photosensitizer in the composition may be appropriately determined according to the types and amounts of the photopolymerization initiator and the polymerizable liquid crystal compound. The content of the photosensitizer in the composition is preferably 0.1 parts by mass or more and 30 parts by mass or less, more preferably 0.5 parts by mass or more and 10 parts by mass or less, and still more preferably 0.5 parts by mass or more and 8 parts by mass or less, based on 100 parts by mass of the polymerizable liquid crystal compound.

### Polymerization Inhibitor

The composition may contain at least one polymerization inhibitor. Examples of the polymerization inhibitor include radical scavengers such as hydroquinone, alkoxy group-containing hydroquinone, alkoxy group-containing catechol (e.g., butylcatechol), pyrogallol, 2,2,6,6-tetramethyl-1-piperidinyl oxyradical; thiophenols; β-naphthylamines; and β-naphthols. When the composition contains the polymerization inhibitor, the polymerization inhibitor can control the promotion degree of the polymerization reaction of the polymerizable liquid crystal compound.

When the composition contains the polymerization inhibitor, the content of the polymerization inhibitor in the composition is preferably 0.1 parts by mass or more and 30 parts by mass or less, more preferably 0.5 parts by mass or more and 10 parts by mass or less, and still more preferably 0.5 parts by mass or more and 8 parts by mass or less, based on 100 parts by mass of the polymerizable liquid crystal compound.

### Leveling Agent

The composition may contain at least one leveling agent. The leveling agent has a function of adjusting the fluidity of the composition and making a coating film, which is obtained by application of the composition, flatter, and specific examples thereof include a surfactant. The leveling agent is preferably at least one selected from the group consisting of a leveling agent containing a polyacrylate compound as a main component and a leveling agent containing a fluorine atom-containing compound as a main component. The leveling agents can be used alone or in combination of two or more.

When the composition contains the leveling agent, the content of the leveling agent is preferably 0.05 parts by mass or more and 5 parts by mass or less, and more preferably 0.05 parts by mass or more and 3 parts by mass or less, based on 100 parts by mass of the total amount of the polymerizable liquid crystal compound and the liquid crystalline polymer compound. When the content of the leveling agent is within the above range, it is made easy to horizontally orientate the polymerizable liquid crystal compound and the liquid crystalline polymer compound, unevenness hardly occurs, and a smoother film, for example, a polarizing film tends to be obtained.

When the content of the leveling agent is within the above range, it is made easy to horizontally orientate the polymerizable liquid crystal compound and the liquid crystalline polymer compound, and a film to be obtained tends to be smoother. If the content of the leveling agent to the polymerizable liquid crystal compound and the liquid crystalline polymer compound exceeds the above range, the film to be obtained easily tends to be uneven.

### Antioxidant

The composition may include an antioxidant. The antioxidant is not particularly limited as long as the composition can exhibit the effect of the present invention, and a known antioxidant can be used. From the viewpoint of having a high effect of suppressing photodegradation of the first compound and the second compound, the antioxidant is preferably a so-called primary antioxidant that traps radicals and has an effect of preventing automatic oxidation. Therefore, the antioxidant contained in the composition is more preferably at least one selected from the group consisting of phenolic compounds, alicyclic alcohol compounds, and amine compounds. As the antioxidant, only one type may be used alone, or two or more types may be used in combination.

The content of the antioxidant in the composition is preferably 0.1 parts by mass or more and 15 parts by mass or less, more preferably 0.3 parts by mass or more, still more preferably 0.5 parts by mass or more, more preferably 12 parts by mass or less, and even more preferably 10 parts by mass or less, based on 100 parts by mass of the composition. When the content of the antioxidant is equal to or more than the above lower limit value, photodegradation of the first compound and the second compound can be more effectively suppressed. When the content of the antioxidant is equal to or less than the above upper limit value, the orientation of the polymerizable liquid crystal compound is more hardly disturbed, and a higher effect of suppressing photodegradation of the first compound and the second compound can be expected.

The composition may contain additives other than those described above. Examples of other additives include colorants such as a mold release agent, a stabilizer, and a bluing agent, a flame retardant, and a lubricant. When the composition contains other additives, the content of the other additives is preferably more than 0% and 20% by mass or less, and more preferably more than 0% and 10% by mass or less, with respect to the solid content of the composition.

The composition can be produced by a conventionally known method of preparing a composition. For example, the composition can be prepared by mixing and stirring the first compound, the second compound, the liquid crystalline compound, and additives such as an antioxidant and a leveling agent as necessary.

### <Film>

The film according to the present embodiment may be a film containing the first compound and the second compound as forming materials, or may be a film obtained by using a composition containing the first compound, the second compound, and a liquid crystalline compound as a forming material. The film formed of the composition may be formed by applying the composition to a substrate and forming a film. When the composition contains a polymerizable liquid crystal compound, a film containing a cured product obtained by polymerizing the polymerizable liquid crystal compound may be formed by applying the composition to a substrate, forming a film, and then polymerizing and curing the polymerizable liquid crystal compound.

The composition can form a film, for example, a polarizing film in which the decrease in dichroic ratio due to photodegradation in the wavelength range of 570 nm or more and 700 nm or less is suppressed. Therefore, the film according to the present embodiment is a polarizing film formed from the composition containing the first compound, the second compound, and the liquid crystalline compound, and includes a polarizing film having excellent maintainability of the dichroic ratio. The composition can form a film having a high degree of orientation order, for example, a polarizing film. Therefore, the film according to the present embodiment is a polarizing film formed from the composition containing the first compound, the second compound, and the liquid crystalline compound, and includes polarizing film having a high degree of orientation order.

Here, in the polarizing film having a high degree of orientation order, the Bragg peak derived from a higher order structure such as a hexatic phase or a crystal phase in X-ray diffractometry is obtained. Therefore, the polarizing film formed from the composition is preferably oriented such that the polymerizable liquid crystal compound or the liquid crystalline polymer compound exhibits the Bragg peak in the X-ray diffraction measurement, and more preferably “horizontally oriented” such that the molecules of the polymerizable liquid crystal compound or the liquid crystalline polymer compound are oriented in a light absorbing direction. The high degree of orientation order exhibiting the Bragg peak can be achieved by controlling the type of the polymerizable liquid crystal compound or liquid crystalline polymer compound to be used, the amounts of the first compound and the second compound, and the like.

The first compound, the second compound, and the liquid crystalline compound constituting the composition used for forming the film are as described above.

The film can be produced, for example, by a method including the following steps:

step A: forming a coating film of a composition containing a first compound, a second compound, a liquid crystalline compound, and a solvent;

step B: removing at least a part of the solvent from the coating film;

step C: raising temperature to a temperature equal to or higher than a temperature at which the liquid crystal compound undergoes phase transition to a liquid phase, then lowering the temperature, and causing the liquid crystalline compound to undergo phase transition to the smectic phase (smectic liquid crystal state); and

step D: if necessary, polymerizing the polymerizable liquid crystal compound while maintaining the smectic phase (smectic liquid crystal state).

The coating film of the composition can be formed, for example, by applying the composition onto a substrate, an orientation film described later, or the like. The composition may be applied directly onto a phase difference film or another layer constituting a polarizing plate.

The substrate is usually a transparent substrate. When the substrate is not installed on a display surface of a display element, for example, when a laminate obtained by removing the substrate from the film is installed on the display surface of the display element, the substrate may not be transparent. The transparent substrate means a substrate having transparency for transmitting light, particularly visible light, and the transparency means a characteristic of a transmittance of 80% or more for light rays with a wavelength of 380 nm or more and 780 nm or less. Specific examples of the transparent substrate include translucent resin substrates.

Examples of the resin constituting the translucent resin substrate include polyolefin; a cycloolefin-based resin; polyvinyl alcohol; polyethylene terephthalate; a polymethacrylic acid ester; a polyacrylic acid ester; cellulose ester; polyethylene naphthalate; polycarbonate; polysulfone; polyether sulfone; polyether ketone; polyphenylenesulfide; and polyphenylene oxide. From the viewpoint of easy availability and transparency, polyethylene terephthalate, polymethacrylic acid ester, cellulose ester, cycloolefin-based resin, or polycarbonate is preferable.

Although the characteristics required for the substrate differ depending on the configuration of the film, a substrate having a phase difference property as small as possible is usually preferable. Examples of the substrate having a phase difference property as small as possible include cellulose ester films having no phase difference such as Zero-TAC (Konica Minolta Opto Inc.) and Z-TAC (Fujifilm Corporation). In addition, an unstretched cycloolefin-based resin substrate is also preferable. A surface of the substrate on which the film is not stacked may be subjected to a hard coat treatment, anti-reflective treatment, antistatic treatment, or the like.

The thickness of the substrate is usually 5 μm or more and 300 μm or less, preferably 20 μm or more and 200 μm or less, and more preferably 20 μm or more and 100 μm or less. When the thickness is equal to or more than the above lower limit value, reduction in strength is suppressed, and workability tends to be improved.

Examples of the method for applying the composition onto the substrate and the like include known methods such as: coating methods including a spin coating method, extrusion method, gravure coating method, die coating method, bar coating method, applicator method, etc.; and printing methods including a flexographic method.

Subsequently, at least a part of the solvent contained in the coating film obtained from the composition is removed by drying or the like to form a dry coating film. When a polymerizable liquid crystal compound is contained in the coating film, drying is performed under a condition that the polymerizable liquid crystal compound is not polymerized to form a dry coating film. Examples of the method of drying the coating film include a natural drying method, ventilation drying method, heat drying method, and decompression drying method.

In addition, in order to cause the liquid crystalline compound to undergo phase transition to the liquid phase, the temperature is raised to the temperature equal to or higher than the temperature at which the liquid crystalline compound undergoes phase transition to the liquid phase, and then lowered to cause the liquid crystalline compound to undergo phase transition to the smectic phase (smectic liquid crystal state). Such phase transition may be performed after removal of the solvent in the coating film, or may be performed simultaneously with removal of the solvent.

When the composition contains a polymerizable liquid crystal compound, a film containing a cured product of the polymerizable liquid crystal compound is formed by polymerizing the polymerizable liquid crystal compound while maintaining the smectic liquid crystal state of the polymerizable liquid crystal compound. The polymerization method is preferably a photopolymerization method. In photopolymerization, the light with which the dried coating film is irradiated is appropriately selected depending on the type of the photopolymerization initiator contained in the dried coating film, the type of the polymerizable liquid crystal compound (particularly, the type of the polymerizable group held by the polymerizable liquid crystal compound), and the amounts thereof. Specific examples of the light include one or more types of light or active electron beams selected from the group consisting of visible light, ultraviolet light, infrared light, X-rays, α-rays, β-rays, and γ-rays. Among them, ultraviolet light is preferable because it is easy to control the progress of the polymerization reaction and a photopolymerization apparatus widely used in the field can be used, and it is preferred to select the types of the polymerizable liquid crystal compound contained in the composition and the polymerization initiator so that photopolymerization can be performed by ultraviolet light. At the time of polymerization, a polymerization temperature can also be controlled by irradiating light while cooling the dried coating film with a suitable cooling unit. When the polymerizable liquid crystal compound is polymerized at a lower temperature by adopting such a cooling unit, a film can be properly formed even if a substrate having a relatively low heat resistance is used. A patterned film can also be obtained by performing masking and development, etc., in the photopolymerization.

Examples of light sources of the active energy rays include a low pressure mercury lamp, a medium pressure mercury lamp, a high pressure mercury lamp, an ultrahigh pressure mercury lamp, a xenon lamp, a halogen lamp, a carbon arc lamp, a tungsten lamp, a gallium lamp, an excimer laser, an LED light source emitting light in a wavelength range of 380 nm or more and 440 nm or less, a chemical lamp, a black light lamp, a microwave-excited mercury lamp, and a metal halide lamp.

The ultraviolet irradiation intensity may be usually 10 mW/cm² or more and 3,000 mW/cm² or less. It is preferable that the ultraviolet irradiation intensity is an intensity within a wavelength region effective for activating the photopolymerization initiator. A period for emitting the light may be usually 0.1 seconds or more and 10 minutes or less, is preferably 0.1 seconds or more and 5 minutes or less, more preferably 0.1 seconds or more and 3 minutes or less, and still more preferably 0.1 seconds or more and 1 minute or less. When ultraviolet rays are irradiated once or multiple times with such an ultraviolet irradiation intensity, the integrated amount of the light is preferably 10 mJ/cm² or more and 3,000 mJ/cm² or less.

By performing photopolymerization, the polymerizable liquid crystal compound is polymerized while maintaining the liquid crystal state of the smectic phase, preferably the higher order smectic phase, and a film is formed. The film obtained by polymerizing the polymerizable liquid crystal compound while maintaining the liquid crystal state of the smectic phase has an advantage of having higher polarization performance also due to the action of the dichroic dye than a conventional host-guest type polarizing film, that is, a film including the liquid crystal state of the nematic phase. In addition, there is also an advantage that strength is excellent as compared with a case where only a dichroic dye or lyotropic liquid crystal is applied.

The thickness of the film can be appropriately selected depending on a display device to be adopted or the like, and is preferably 0.5 μm or more and 10 μm or less, more preferably 1 μm or more and 5 μm or less, and still more preferably 1 μm or more and 3 μm or less.

When the film is used as a polarizing film, the film is preferably formed on an orientation film. The orientation film has an orientation regulating force by which the polymerizable liquid crystal compound and the liquid crystalline polymer compound are liquid-crystal-oriented in a desired direction. Preferably, the orientation film has a solvent resistance with which it does not dissolve when a composition containing the liquid crystalline compound containing at least one of the polymerizable liquid crystal compound and the liquid crystalline polymer compound is coated, and has a heat resistance for a heat treatment for removing the solvent or orienting the polymerizable liquid crystal compound. Examples of the orientation film include an orientation film containing an orientation polymer, a photo-orientation film, and a groove orientation film having an uneven pattern or a plurality of grooves on the surface, and a photo-orientation film is preferable from the viewpoint of accuracy of an orientation angle and the quality.

### <Laminate>

The laminate according to the present embodiment may include the film containing the first compound and the second compound as the forming materials, or may include the film including the composition containing the first compound, the second compound, and the liquid crystalline compound as the forming material. The laminate may include a substrate and the film containing the first compound and the second compound arranged on the substrate as the forming materials, and may include the substrate, an orientation film disposed on the substrate, and the film including the first compound and the second compound arranged on the orientation film as the forming materials. The film containing the first compound and the second compound as the forming materials may constitute a polarizing film. The substrate may be a phase difference film. The laminate can constitute, for example, a polarizing plate. The laminate can be produced, for example, by forming a film on a substrate in accordance with the film production method described above.

The thickness of the laminate is preferably 10 μm or more and 300 μm or less, more preferably 20 μm or more and 200 μm or less, and still more preferably 25 μm or more and 100 μm or less from the viewpoint of flexibility and visibility of the display device.

When the laminate includes a phase difference film as a substrate, the thickness of the phase difference film can be appropriately selected depending on a display device to be adopted.

### <Display Device>

The display device of the present embodiment may include the laminate, and the laminate may be a polarizing plate. The display device can be obtained, for example, by attaching the laminate as the polarizing plate to both surfaces of the display device via a pressure-sensitive adhesive layer. The display device is a device having a display element, and includes a light emitting element or a light emitting device as a light emitting source. Examples of the display device include a liquid crystal display device, an organic electroluminescence (EL) display device, an inorganic electroluminescence (EL) display device, an electron emission display device (e.g., a field emission display device (FED), surface-conduction electron-emitter display (SED)), an electronic paper (a display device with an electronic ink, an electrophoresis element, or the like), a plasma display device, a projection type-display device (e.g., a grating light valve (GLV) display device, a display device including a digital micromirror device (DMD)), and a piezoceramic display. The liquid crystal display device may include a transmissive liquid crystal display, a semi-transmissive liquid crystal display, a reflective liquid crystal display, a direct viewing liquid crystal display, and a projection liquid crystal display. These display devices may also be display devices displaying a two-dimensional image or stereoscopic display devices displaying a three-dimensional image. In particular, an organic EL display device and a touch panel display device are preferable as a display device, and in particular, the organic EL display device is preferable.

### <Dichroic Dye>

The dichroic dye contains at least one of the first compounds and at least one of the second compounds as active ingredients. By containing the first compound and the second compound, the dichroic dye can form a polarizing film in which the decrease in dichroic ratio due to photodegradation in the wavelength range of 570 nm or more and 700 nm or less is suppressed. The dichroic dye may contain only one type of each of the first compound and the second compound, or may contain two or more types having different structures in combination. When the dichroic dye contains two or more types of the first compounds or the second compounds, the compounds may have different maximum absorption wavelengths from each other. The dichroic dye may contain other dye compounds in addition to the first compound and the second compound. The other dye compounds are as described above.

### EXAMPLES

Hereinafter, the present invention is more specifically described with reference to Examples; however, the present invention is not limited to these Examples. Unless otherwise specified, “part(s)” and “%” are indicated on a mass basis.

### Synthesis Example 1: Synthesis of Compound (1-1)

In order to synthesize a compound (1-1), a compound (1-1-a) was first synthesized. Subsequently, dehydration condensation esterification was performed to obtain the compound (1-1).

### Synthesis of Compound (1-1-a)

4-Amino-2-fluorobenzoic acid (7.76 g, 50.0 mmol), 35% hydrochloric acid (13.2 mL, 150 mmol), and water (100 mL) were mixed and cooled from 0° C. to 5° C., and a solution of sodium nitrite (3.55 g, 51.5 mmol) in water (6.5 mL) was added dropwise thereto. Thereafter, the mixture was stirred for 30 minutes while maintaining the temperature at 0° C. to 5° C. to prepare a diazo liquid. On the other hand, N,N-dimethylaniline (9.10 g, 75.1 mmol), sodium acetate (16.4 g, 200 mmol), methanol (67.0 mL), and water (33.0 mL) were mixed and cooled from 0° C. to 5° C., and the whole amount of the diazo liquid prepared above was added dropwise. After completion of the dropwise addition, the temperature was raised to normal temperature, and the precipitated solid was filtered off to obtain a compound (1-1-b) (14.0 g, yield 97%).

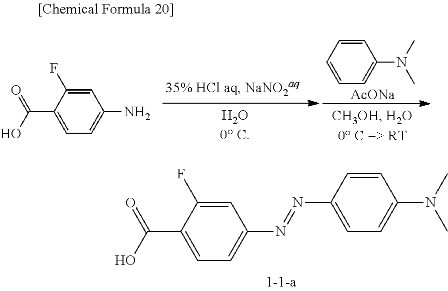

### Synthesis of Compound (1-1)

A compound (1-1-a) (0.717 g, 2.50 mmol), 4-n-octyloxyphenol (0.617 g, 2.78 mmol), DMAP (abbreviation for N, N-dimethylaminopyridine, 32.6 mg, 0.267 mmol), and tetrahydrofuran (25.0 mL) were mixed, EDC-HCl (abbreviation for 1-ethyl-3-(3-dimethylaminopropyl) carbodiimide hydrochloride, 0.719 g, 3.75 mmol) was added, and the reaction solution was stirred at normal temperature for 3 days. Water was added to the reaction solution, and the precipitated solid was filtered off and washed with methanol. The resulting solid was purified by silica gel column chromatography using chloroform as an eluent to obtain a compound (1-1) (0.701 g, yield 51%).

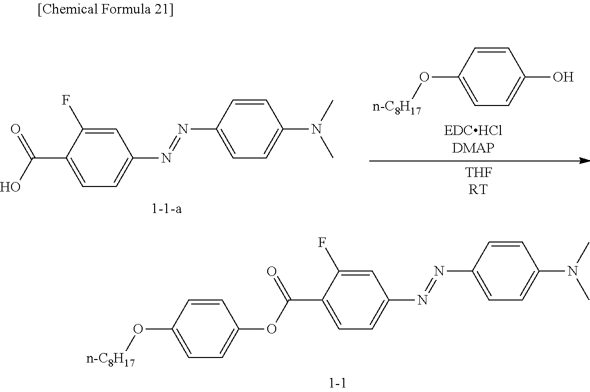

¹H-NMR (400 MHz, CDCl₃): δ (ppm)=8.19 (dd, 1H), 7.94-7.90 (m, 2H), 7.73 (dd, 1H), 7.63 (dd, 1H), 7.17-7.13 (m, 2H), 6.95-6.91 (m, 2H), 6.79-6.75 (m, 2H), 3.96 (t, 2H), 3.13 (s, 6H), 1.79 (quin, 2H), 1.50-1.43 (m, 2H), 1.40-1.25 (m, 8H), 0.90 (t, 3H).

### Synthesis Example 2: Synthesis of Compound (1-2)

In order to synthesize a compound (1-2), first, a compound (1-2-d) was synthesized via a compound (1-2-a), a compound (1-2-b), and a compound (1-2-c). Subsequently, alkylation was performed to obtain the compound (1-2).

### Synthesis of Compound (1-2-a)

4′-Aminoacetanilide (7.51 g, 50.0 mmol), 35% hydrochloric acid (6.6 mL, 75 mmol), and water (150 mL) were mixed and cooled from 0° C. to 5° C., and a solution of sodium nitrite (5.18 g, 75.0 mmol) in water (10.0 mL) was added dropwise thereto. Thereafter, the mixture was stirred for 60 minutes while maintaining the temperature at 0° C. to 5° C., and a solution of amidosulfuric acid (2.43 g, 25.0 mmol) in water (15.0 mL) was further added dropwise to prepare a diazo liquid. On the other hand, phenol (7.07 g, 75.1 mmol), sodium acetate (12.3 g, 150 mmol), and water (250 mL) were mixed and cooled from 0° C. to 5° C., and the whole amount of the diazo liquid prepared above was added dropwise. After completion of the dropwise addition, the temperature was raised to normal temperature, and the precipitated solid was filtered off to obtain the compound (1-2-a) (7.58 g, yield 59%).

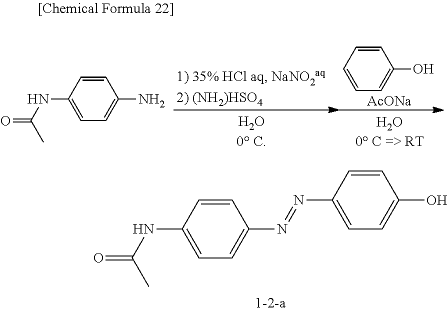 [SMILES: "AcONa" ; CC(=O)Nc1ccc(N)cc1 ; Oc1ccccc1 ; CC(=O)Nc1ccc(/N=N/c2ccc(O)cc2)cc1]

### Synthesis of Compound (1-2-b)

The compound (1-2-a) (5.11 g, 20.0 mmol), iodomethane (14.2 g, 100 mmol), potassium carbonate (8.29 g, 60.0 mmol), and N,N-dimethylacetamide (50 mL) were mixed, and the mixture was heated and stirred at 50° C. for 3 hours. Water was added to the reaction solution, and the precipitated solid was filtered off to obtain the compound (1-2-b) (5.04 g, yield 94%).

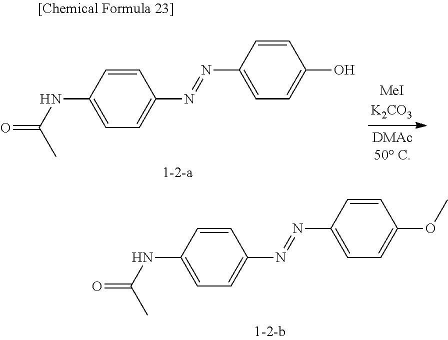 [SMILES: CC(=O)Nc1ccc(/N=N/c2ccc(O)cc2)cc1 ; COc1ccc(/N=N/c2ccc(NC(C)=O)cc2)cc1]

### Synthesis of Compound (1-2-c)

The compound (1-2-b) (5.39 g, 20.0 mmol), sodium hydroxide (20.0 g, 501 mmol), methanol (20 mL), and water (10 mL) were mixed, and the mixture was heated and stirred at 110° C. for 8 hours. The solid was filtered off to obtain the compound (1-2-c) (4.25 g, yield 93%).

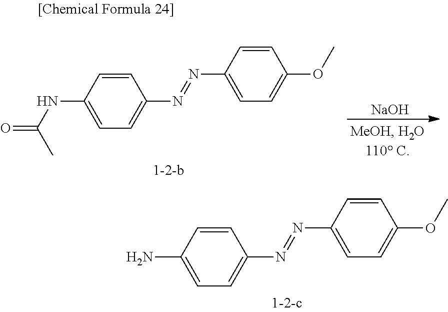 [SMILES: COc1ccc(/N=N/c2ccc(NC(C)=O)cc2)cc1 ; "NaOH" ; COc1ccc(/N=N/c2ccc(N)cc2)cc1]

### Synthesis of Compound (1-2-d)

The compound (1-2-c) (1.36 g, 6.00 mmol), 35% hydrochloric acid (1.6 mL, 18 mmol), acetic acid (18.0 mL), and water (18.0 mL) were mixed and cooled from 0° C. to 5° C., and a solution of sodium nitrite (0.433 g, 6.28 mmol) in water (0.80 mL) was added dropwise thereto. Thereafter, the mixture was stirred for 30 minutes while maintaining the temperature at 0° C. to 5° C. to prepare a diazo liquid. On the other hand, 2-fluorophenol (1.02 g, 9.11 mmol), sodium acetate (1.98 g, 24.1 mmol), methanol (24.0 mL), and water (12.0 mL) were mixed and cooled from 0° C. to 5° C., and the whole amount of the diazo liquid prepared above was added dropwise. After completion of the dropwise addition, the temperature was raised to normal temperature, and the mixture was stirred for 5 hours. The precipitated solid was filtered off to obtain a compound (1-2-d) (1.77 g, yield 84%).

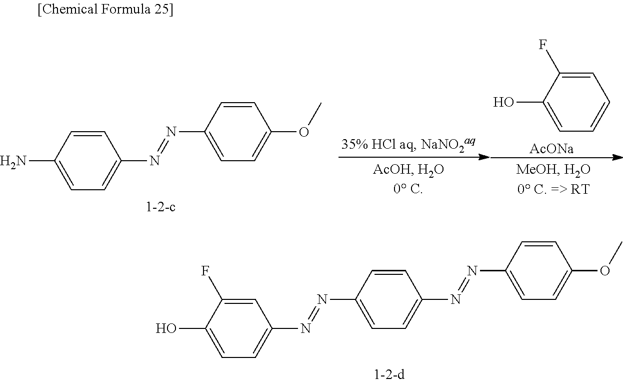 [SMILES: "AcONa" ; COc1ccc(/N=N/c2ccc(N)cc2)cc1 ; Oc1ccccc1F ; COc1ccc(/N=N/c2ccc(/N=N/c3ccc(O)c(F)c3)cc2)cc1]

### Synthesis of Compound (1-2)

The compound (1-2-d) (0.353 g, 1.01 mmol), 1-iodobutane (0.372 g, 2.02 mmol), potassium carbonate (0.424 g, 3.01 mmol), and N,N-dimethylacetamide (5.0 mL) were mixed, and the mixture was heated and stirred at 90° C. for 1 hour. Methanol was added to the reaction solution, and the precipitated solid was filtered off. The resulting solid was purified by silica gel column chromatography using chloroform as an eluent, and further purified by reprecipitation from chloroform/methanol to obtain a compound (1-2) (0.302 g, yield 74%).

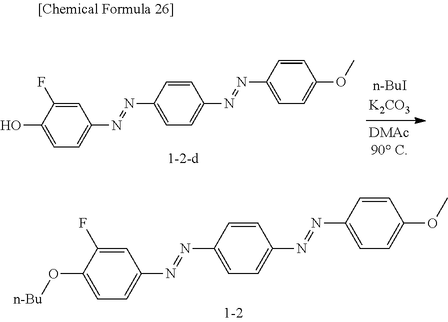

¹H-NMR (400 MHz, CDCl₃): δ (ppm)=8.01 (s, 4H), 7.98-7.94 (m, 2H), 7.81-7.78 (m, 1H), 7.73 (dd, 1H), 7.09 (dd, 1H), 7.06-7.02 (m, 2H), 4.14 (t, 2H), 3.91 (s, 3H), 1.87 (quin, 2H), 1.55 (sext, 2H), 1.01 (t, 3H).

### Synthesis Example 3: Synthesis of Compound (1-3)

In order to synthesize a compound (1-3), a compound (1-3-a) was synthesized using the compound (1-2-c) as a raw material. Subsequently, alkylation was performed to obtain the compound (1-3).

### Synthesis of Compound (1-3-a)

The compound (1-2-c) (1.64 g, 7.00 mmol), 35% hydrochloric acid (1.85 mL, 21.0 mmol), acetic acid (21.0 mL), and water (21.0 mL) were mixed and cooled from 0° C. to 5° C., and a solution of sodium nitrite (0.509 g, 7.38 mmol) in water (1.00 mL) was added dropwise thereto. Thereafter, the mixture was stirred for 30 minutes while maintaining the temperature at 0° C. to 5° C. to prepare a diazo liquid. On the other hand, 2,6-difluorophenol (1.40 g, 10.5 mmol), sodium acetate (2.31 g, 28.2 mmol), methanol (28.0 mL), and water (14.0 mL) were mixed and cooled from 0° C. to 5° C., and the whole amount of the diazo liquid prepared above was added dropwise. After completion of the dropwise addition, the temperature was raised to normal temperature, and the mixture was stirred for 5 hours. The precipitated solid was filtered off to obtain a compound (1-3-a) (2.34 g, yield 91%).

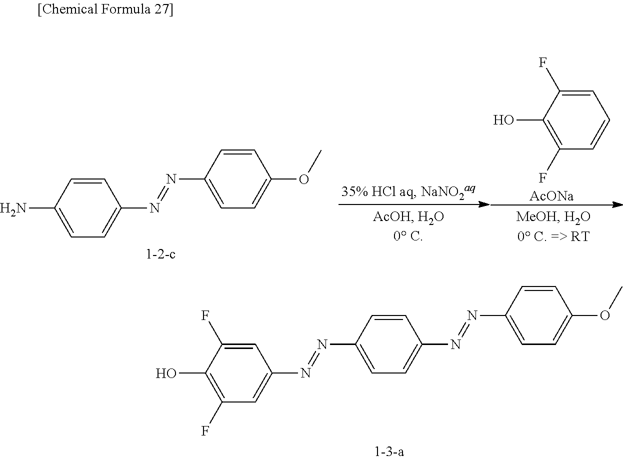 [SMILES: "AcONa" ; COc1ccc(/N=N/c2ccc(N)cc2)cc1 ; Oc1c(F)cccc1F ; COc1ccc(/N=N/c2ccc(/N=N/c3cc(F)c(O)c(F)c3)cc2)cc1]

### Synthesis of Compound (1-3)

The compound (1-3-a) (0.368 g, 1.00 mmol), 1-iodobutane (0.372 g, 2.02 mmol), potassium carbonate (0.423 g, 3.00 mmol), and N,N-dimethylacetamide (5.0 mL) were mixed, and the mixture was heated and stirred at 100° C. for 30 minutes. Methanol was added to the reaction solution, and the precipitated solid was filtered off. The resulting solid was purified by silica gel column chromatography using chloroform as an eluent, and further purified by reprecipitation from chloroform/methanol to obtain a compound (1-2) (0.309 g, yield 73%).

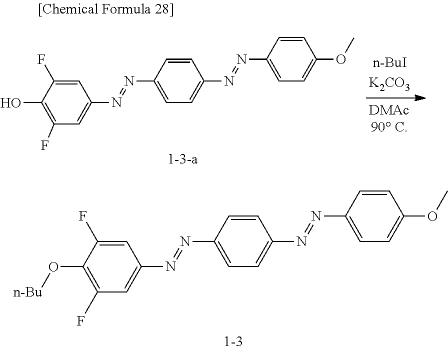

¹H-NMR (400 MHz, CDCl₃): δ (ppm)=8.02 (s, 4H), 7.99-7.95 (m, 2H), 7.61-7.54 (m, 2H), 7.06-7.02 (m, 2H), 4.27 (t, 2H), 3.92 (s, 3H), 1.80 (quin, 2H), 1.53 (sext, 2H), 0.99 (t, 3H).

### Synthesis Example 4: Synthesis of Compound (1-4)

In order to synthesize a compound (1-4), first, a compound (1-4-d) was synthesized via a compound (1-4-a), a compound (1-4-b), and a compound (1-4-c). Subsequently, alkylation was performed to obtain the compound (1-4).

### Synthesis of Compound (1-4-a)

3-Fluoro-4-nitroaniline (2.12 g, 13.6 mmol), 35% hydrochloric acid (3.60 mL, 40.8 mmol), acetic acid (13.5 mL), and water (13.5 mL) were mixed and cooled from 0° C. to 5° C., and a solution of sodium nitrite (5.18 g, 75.0 mmol) in water (10.0 mL) was added dropwise thereto. Thereafter, the mixture was stirred for 60 minutes while maintaining the temperature at 0° C. to 5° C. to prepare a diazo liquid. On the other hand, phenol (1.97 g, 20.5 mmol), sodium acetate (4.51 g, 55.0 mmol), and water (27.0 mL) were mixed and cooled from 0° C. to 5° C., and the whole amount of the diazo liquid prepared above was added dropwise. After completion of the dropwise addition, the temperature was raised to normal temperature, and the precipitated solid was filtered off to obtain the compound (1-4-a) (3.44 g, yield 97%).

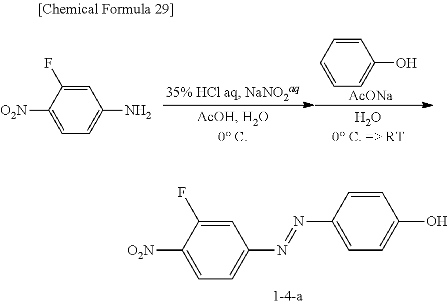 [SMILES: "AcONa" ; Nc1ccc([N+](=O)[O-])c(F)c1 ; Oc1ccccc1 ; O=[N+]([O-])c1ccc(/N=N/c2ccc(O)cc2)cc1F]

### Synthesis of Compound (1-4-b)

The compound (1-4-a) (1.57 g, 6.00 mmol), iodoethane (1.88 g, 12.1 mmol), potassium carbonate (2.54 g, 18.0 mmol), and N,N-dimethylacetamide (12.0 mL) were mixed, and the mixture was heated and stirred at 70° C. for 30 minutes. Water was added to the reaction solution, and the precipitated solid was filtered off to obtain the compound (1-4-b) (1.67 g, yield 96%).

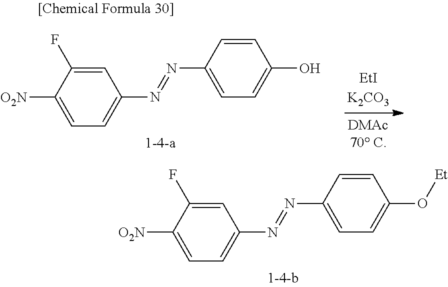 [SMILES: O=[N+]([O-])c1ccc(/N=N/c2ccc(O)cc2)cc1F ; CCOc1ccc(/N=N/c2ccc([N+](=O)[O-])c(F)c2)cc1]

### Synthesis of Compound (1-4-c)

The compound (1-4-b) (1.62 g, 5.60 mmol), sodium sulfide nonahydrate (2.77 g, 11.3 mmol), ethanol (14 mL), and water (14 mL) were mixed, and the mixture was heated and refluxed for 30 minutes. Water was added to the reaction solution, and the precipitated solid was filtered off to obtain the compound (1-4-c) (0.981 g, yield 67%).

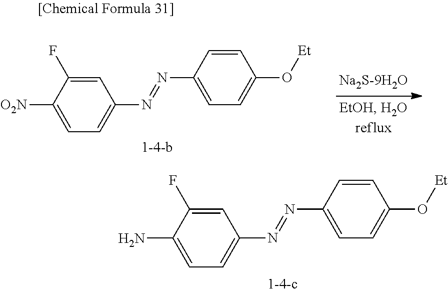 [SMILES: CCOc1ccc(/N=N/c2ccc([N+](=O)[O-])c(F)c2)cc1 ; CCOc1ccc(/N=N/c2ccc(N)c(F)c2)cc1]

### Synthesis of Compound (1-4-d)

The compound (1-4-c) (0.908 g, 3.50 mmol), 35% hydrochloric acid (0.95 mL, 11 mmol), acetic acid (11.0 mL), and water (11.0 mL) were mixed and cooled from 0° C. to 5° C., and a solution of sodium nitrite (0.433 g, 6.28 mmol) in water (0.80 mL) was added dropwise thereto. Thereafter, the mixture was stirred for 30 minutes while maintaining the temperature at 0° C. to 5° C. to prepare a diazo liquid. On the other hand, 2-fluorophenol (0.595 g, 5.30 mmol), sodium acetate (1.16 g, 14.1 mmol), methanol (14.0 mL), and water (7.0 mL) were mixed and cooled from 0° C. to 5° C., the whole amount of the diazo liquid prepared above was added dropwise, and the mixture was stirred for 2 hours while maintaining the temperature from 0° C. to 5° C. After the temperature was raised to normal temperature, the precipitated solid was filtered off to obtain the compound (1-4-d) (1.17 g, yield 88%).

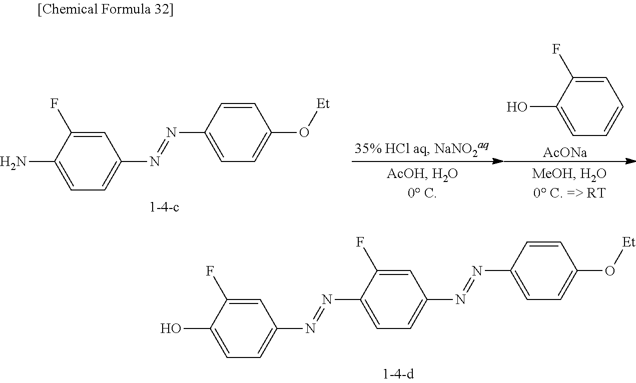 [SMILES: "AcONa" ; CCOc1ccc(/N=N/c2ccc(N)c(F)c2)cc1 ; Oc1ccccc1F ; CCOc1ccc(/N=N/c2ccc(/N=N/c3ccc(O)c(F)c3)c(F)c2)cc1]

### Synthesis of Compound (1-4)

The compound (1-4-d) (0.574 g, 1.50 mmol), 1-iodobutane (0.558 g, 3.03 mmol), potassium carbonate (0.635 g, 4.51 mmol), and N,N-dimethylacetamide (7.5 mL) were mixed, and the mixture was heated and stirred at 100° C. for 1 hour. Methanol was added to the reaction solution, and the precipitated solid was filtered off. The resulting solid was purified by silica gel column chromatography using toluene as an eluent, and further purified by reprecipitation from chloroform/methanol to obtain a compound (1-4) (0.373 g, yield 57%).

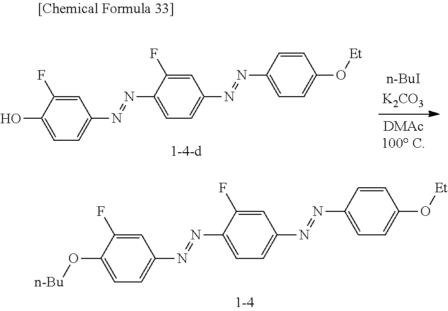

¹H-NMR (400 MHz, CDCl₃): δ (ppm)=7.97-7.93 (m, 2H), 7.88 (dd, 1H), 7.83-7.74 (m, 4H), 7.09 (dd, 1H), 7.04-7.00 (m, 2H), 4.17-4.12 (m, 4H), 1.87 (quin, 2H), 1.55 (sext, 2H), 1.47 (t, 3H), 1.01 (t, 3H).

### Synthesis Example 5: Synthesis of Compound (1-5)

In order to synthesize a compound (1-5), a compound (1-5-a) was synthesized using the compound (1-4-c) as a raw material. Subsequently, alkylation was performed to obtain the compound (1-5).

### Synthesis of Compound (1-5-a)

The compound (1-4-c) (0.803 g, 3.00 mmol), 35% hydrochloric acid (0.80 mL, 9.1 mmol), acetic acid (9.0 mL), and water (9.0 mL) were mixed and cooled from 0° C. to 5° C., and a solution of sodium nitrite (0.219 g, 3.17 mmol) in water (0.50 mL) was added dropwise thereto. Thereafter, the mixture was stirred for 30 minutes while maintaining the temperature at 0° C. to 5° C. to prepare a diazo liquid. On the other hand, 2,6-difluorophenol (1.40 g, 10.5 mmol), sodium acetate (2.31 g, 28.2 mmol), methanol (28.0 mL), and water (14.0 mL) were mixed and cooled from 0° C. to 5° C., the whole amount of the diazo liquid prepared above was added dropwise, and the mixture was stirred for 2 hours while maintaining the temperature from 0° C. to 5° C. After the temperature was raised to normal temperature, the precipitated solid was filtered off to obtain the compound (1-5-a) (1.04 g, yield 91%).

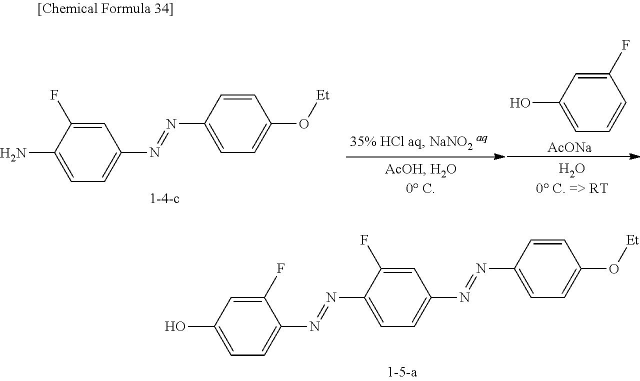 [SMILES: "AcONa" ; CCOc1ccc(/N=N/c2ccc(N)c(F)c2)cc1 ; Oc1cccc(F)c1 ; CCOc1ccc(/N=N/c2ccc(/N=N/c3ccc(O)cc3F)c(F)c2)cc1]

### Synthesis of Compound (1-5)

The compound (1-5-a) (0.383 g, 1.00 mmol), 1-iodobutane (0.373 g, 2.03 mmol), potassium carbonate (0.423 g, 3.00 mmol), and N,N-dimethylacetamide (5.0 mL) were mixed, and the mixture was heated and stirred at 100° C. for 30 minutes. Methanol was added to the reaction solution, and the precipitated solid was filtered off. The resulting solid was purified by silica gel column chromatography using toluene as an eluent, and further purified by reprecipitation from chloroform/methanol to obtain a compound (1-5) (0.218 g, yield 50%).

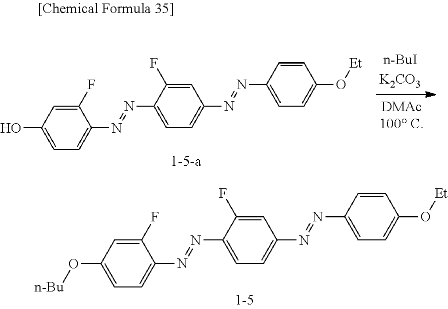

¹H-NMR (400 MHz, CDCl₃): δ (ppm)=7.97-7.84 (m, 4H), 7.79-7.74 (m, 2H), 7.04-7.00 (m, 2H), 6.79-6.75 (m, 2H), 4.15 (q, 2H), 4.05 (t, 2H), 1.82 (quin, 2H), 1.57-1.46 (m, 5H), 1.00 (t, 3H).

### Synthesis Example 6: Synthesis of Compound (1-64)

A compound (1-64) was obtained by dehydration condensation esterification using the compound (1-1-a) as a raw material.

### Synthesis of Compound (1-64)

The compound (1-1-a) (0.288 g, 1.00 mmol), 4-n-butylphenol (0.183 g, 1.22 mmol), DMAP (15.2 mg, 0.124 mmol), and tetrahydrofuran (10.0 mL) were mixed, EDC-HCl (0.286 g, 1.49 mmol) was added, and the reaction solution was stirred at normal temperature for 2 days. Water was added to the reaction solution, and the precipitated solid was filtered off and washed with methanol. The resulting solid was purified by silica gel column chromatography using chloroform as an eluent to obtain a compound (1-64) (0.248 g, yield 48%).

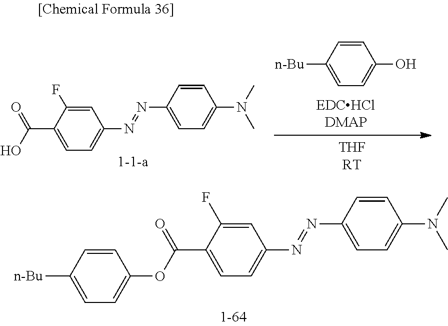

¹H-NMR (400 MHz, CDCl₃): δ (ppm)=8.19 (dd, 1H), 7.94-7.90 (m, 2H), 7.73 (dd, 1H), 7.63 (dd, 1H), 7.25-7.22 (m, 2H), 7.17-7.13 (m, 2H), 6.79-6.75 (m, 2H), 3.13 (s, 6H), 2.64 (t, 2H), 1.62 (quin, 2H), 1.38 (sext, 2H), 0.94 (t, 3H).

### Synthesis Example 7: Synthesis of Compound (1-65)

A compound (1-65) was obtained by dehydration condensation esterification using the compound (1-1-a) as a raw material.

### Synthesis of Compound (1-65)

The compound (1-1-a) (2.00 g, 6.84 mmol), 4-(trans-4-butylcyclohexyl) phenol (1.95 g, 8.20 mmol), DMAP (84.4 mg, 0.684 mmol), and chloroform (20.0 mL) were mixed, the mixture was cooled from 0° C. to 5° C., and DIC (abbreviation for N,N-diisopropylcarbodiimide, 1.2 mL, 7.5 mmol) was added dropwise thereto. Thereafter, the mixture was stirred for 2 hours while maintaining the temperature at 0° C. to 5° C., the temperature was raised to normal temperature, and the mixture was stirred for 1.5 hours. The reaction solution was subjected to silica filtration, and the filtrate was concentrated and then purified by recrystallization using methanol and chloroform to obtain the compound (1-65) (2.51 g, yield 73%).

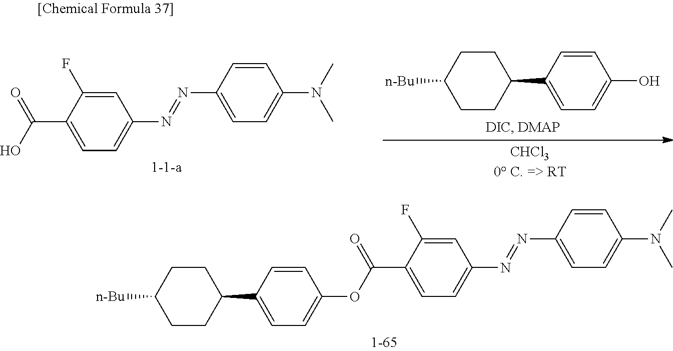

¹H-NMR (400 MHz, CDCl₃): δ (ppm)=8.19 (dd, 1H), 7.94-7.90 (m, 2H), 7.73 (dd, 1H), 7.63 (dd, 1H), 7.28-7.24 (m, 2H), 7.18-7.14 (m, 2H), 6.79-6.75 (m, 2H), 3.13 (s, 6H), 2.53-2.46 (m, 1H), 1.94-1.86 (m, 4H), 1.51-1.40 (m, 2H), 1.33-1.21 (m, 7H), 1.11-1.01 (m, 2H), 0.91 (t, 3H).

### Synthesis Example 8: Synthesis of Compound (1-66)

In order to synthesize a compound (1-66), first, a compound (1-66-d) was synthesized via a compound (1-66-a), a compound (1-66-b), and a compound (1-66-c). Subsequently, alkylation was performed to obtain the compound (1-66).

### Synthesis of Compound (1-66-a)

4-Nitroaniline (6.91 g, 50.0 mmol), 35% hydrochloric acid (13.2 mL, 150 mmol), acetic acid (50.0 mL), and water (50.0 mL) were mixed and cooled from 0° C. to 5° C., and a solution of sodium nitrite (3.55 g, 51.5 mmol) in water (6.5 mL) was added dropwise thereto over 20 minutes to prepare a diazo liquid. On the other hand, phenol (7.22 g, 75.2 mmol), sodium acetat (16.5 g, 202 mmol), and water (100 mL) were mixed and cooled from 0° C. to 5° C., and the whole amount of the diazo liquid prepared above was added dropwise over 20 minutes. After completion of the dropwise addition, the temperature was raised to normal temperature, and the precipitated solid was filtered off to obtain the compound (1-66-a) (11.7 g, yield 96%).

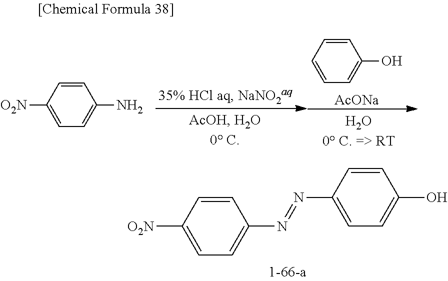 [SMILES: "AcONa" ; Oc1ccccc1 ; Nc1ccc([N+](=O)[O-])cc1 ; O=[N+]([O-])c1ccc(/N=N/c2ccc(O)cc2)cc1]

### Synthesis of Compound (1-66-b)

The compound (1-66-a) (3.65 g, 15.00 mmol), iodoethan (4.69 g, 30.1 mmol), potassium carbonate (6.35 g, 45.0 mmol), and N,N-dimethylacetamide (30.0 mL) were mixed, and the mixture was heated and stirred at 70° C. for 1 hour. Water was added to the reaction solution, and the precipitated solid was filtered off to obtain the compound (1-66-b) (3.98 g, yield 98%).

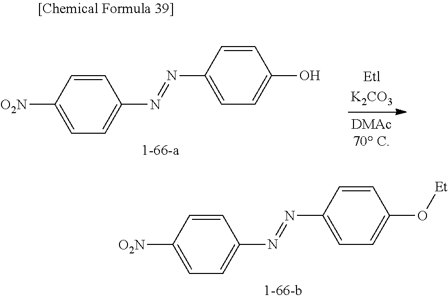 [SMILES: O=[N+]([O-])c1ccc(/N=N/c2ccc(O)cc2)cc1 ; CCOc1ccc(/N=N/c2ccc([N+](=O)[O-])cc2)cc1]

### Synthesis of Compound (1-66-c)

The compound (1-66-b) (3.80 g, 14.0 mmol), sodium sulfide nonahydrate (6.88 g, 28.1 mmol), ethanol (35 mL), and water (35 mL) were mixed, and the mixture was heated and refluxed for 30 minutes. Water was added to the reaction solution, and the precipitated solid was filtered off to obtain the compound (1-66-c) (3.06 g, yield 90%).

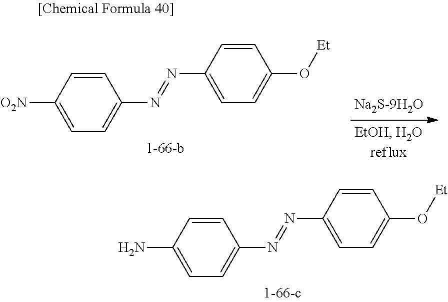 [SMILES: CCOc1ccc(/N=N/c2ccc([N+](=O)[O-])cc2)cc1 ; CCOc1ccc(/N=N/c2ccc(N)cc2)cc1]

### Synthesis of Compound (1-66-d)

The compound (1-66-c) (0.996 g, 4.00 mmol), 35% hydrochloric acid (1.05 mL, 11.9 mmol), acetic acid (12.0 mL), and water (12.0 mL) were mixed and cooled from 0° C. to 5° C., and a solution of sodium nitrite (0.290 g, 4.21 mmol) in water (0.60 mL) was added dropwise thereto over 5 minutes to prepare a diazo liquid. On the other hand, 3-fluorophenol (0.700 g, 6.12 mmol), sodium acetate (1.41 g, 17.2 mmol), and water (24.0 mL) were mixed and cooled from 0° C. to 5° C., the whole amount of the diazo liquid prepared above was added dropwise over 5 minutes, and the mixture was stirred for 1 hour while maintaining the temperature from 0° C. to 5° C. After the temperature was raised to normal temperature, the mixture was stirred for another 1 day. The precipitated solid was filtered off to obtain a compound (1-66-d) (1.32 g, yield 91%).

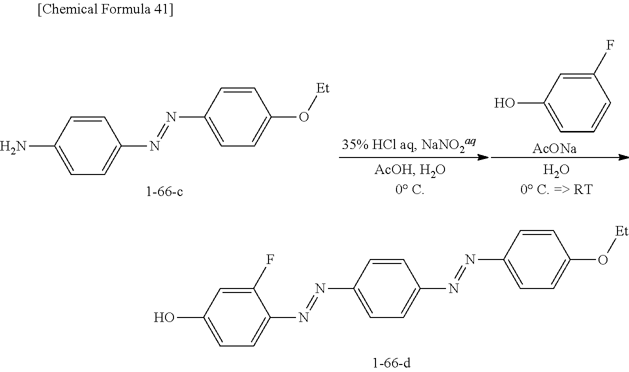 [SMILES: "AcONa" ; CCOc1ccc(/N=N/c2ccc(N)cc2)cc1 ; Oc1cccc(F)c1 ; CCOc1ccc(/N=N/c2ccc(/N=N/c3ccc(O)cc3F)cc2)cc1]

### Synthesis of Compound (1-66)

The compound (1-66-d) (0.367 g, 1.01 mmol), 1-iodobutane (0.374 g, 2.03 mmol), potassium carbonate (0.423 g, 3.00 mmol), and N,N-dimethylacetamide (5.0 mL) were mixed, and the mixture was heated and stirred at 100° C. for 30 minutes. Methanol was added to the reaction solution, and the precipitated solid was filtered off. The resulting solid was purified by silica gel column chromatography using chloroform as an eluent, and further purified by reprecipitation from chloroform/methanol to obtain a compound (1-66) (0.199 g, yield 47%).

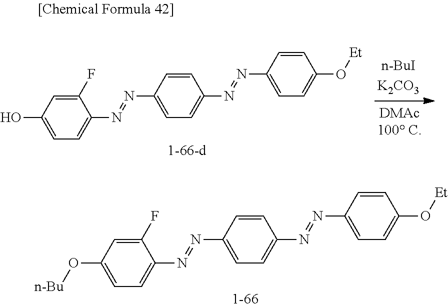

¹H-NMR (400 MHz, CDCl₃): δ (ppm)=8.05-7.99 (m, 4H), 7.97-7.93 (m, 2H), 7.83 (dd, 1H), 7.04-7.00 (m, 2H), 6.80-6.75 (m, 2H), 4.14 (q, 2H), 4.04 (t, 2H), 1.82 (quin, 2H), 1.52 (sext, 2H), 1.47 (t, 3H), 1.00 (t, 3H).

### Synthesis Example 9: Synthesis of Compound (1-67)

In order to synthesize a compound (1-67), a compound (1-67-a) was synthesized using the compound (1-66-c) as a raw material. Subsequently, alkylation was performed to obtain the compound (1-67).

### Synthesis of Compound (1-67-a)

The compound (1-66-c) (0.919 g, 3.81 mmol), 35% hydrochloric acid (1.00 mL, 11.3 mmol), acetic acid (3.8 mL), and water (3.8 mL) were mixed and cooled from 0° C. to 5° C., and a solution of sodium nitrite (0.278 g, 4.02 mmol) in water (0.50 mL) was added dropwise thereto to prepare a diazo liquid. On the other hand, 2,5-difluorophenol (0.722 g, 5.44 mmol), sodium acetate (1.26 g, 15.4 mmol), and water (15.0 mL) were mixed and cooled from 0° C. to 5° C., the whole amount of the diazo liquid prepared above was added dropwise, and the mixture was stirred for 1 hour while maintaining the temperature from 0° C. to 5° C. After the temperature was raised to 50° C., the mixture was stirred for another 1 hour. The precipitated solid was filtered off to obtain a compound (1-67-a) (1.40 g, yield 96%).

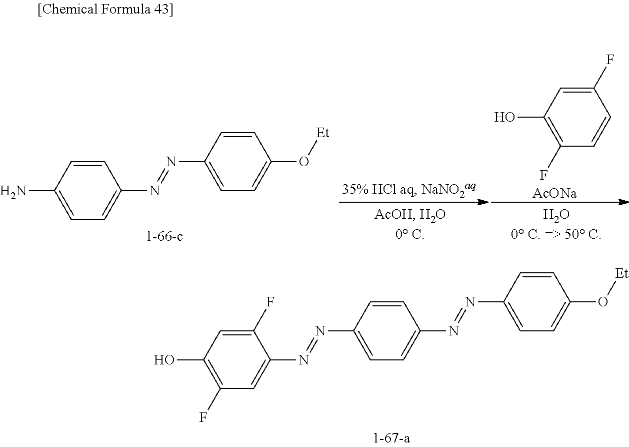 [SMILES: "AcONa" ; CCOc1ccc(/N=N/c2ccc(N)cc2)cc1 ; Oc1cc(F)ccc1F ; CCOc1ccc(/N=N/c2ccc(/N=N/c3cc(F)c(O)cc3F)cc2)cc1]

### Synthesis of Compound (1-67)

The compound (1-67-a) (0.384 g, 1.00 mmol), 1-iodobutane (0.373 g, 2.03 mmol), potassium carbonate (0.431 g, 3.05 mmol), and N,N-dimethylacetamide (10.0 mL) were mixed, and the mixture was heated and stirred at 100° C. for 30 minutes. Methanol was added to the reaction solution, and the precipitated solid was filtered off. The resulting solid was purified by preparative GPC using chloroform as a mobile phase, and further purified by reprecipitation from chloroform/methanol to obtain a compound (1-67) (0.222 g, yield 50%).

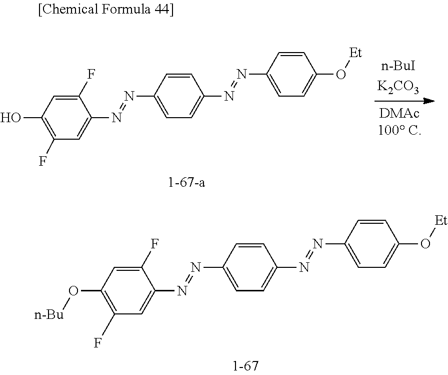

¹H-NMR (400 MHz, CDCl₃): δ (ppm)=8.05-7.99 (m, 4H), 7.97-7.93 (m, 2H), 7.66 (dd, 1H), 7.04-7.00 (m, 2H), 6.86 (dd, 1H), 4.14 (q, 2H), 4.11 (t, 2H), 1.87 (quin, 2H), 1.55 (sext, 2H), 1.47 (t, 3H), 1.01 (t, 3H).

### Synthesis Example 10: Synthesis of Compound (1-68)

In order to synthesize a compound (1-68), a compound (1-68-b) was synthesized via a compound (1-68-a) using the compound (1-66-a) as a raw material. Subsequently, alkylation was performed to obtain the compound (1-68).

### Synthesis of Compound (1-68-a)

The compound (1-66-a) (0.973 g, 4.00 mmol), sodium sulfide nonahydrate (2.00 g, 8.14 mmol), ethanol (c mL), and water (4.0 mL) were mixed, and the mixture was heated and refluxed for 30 minutes. The reaction solution was poured into a solution of ammonium chloride (1.00 g) in water (50 mL), and the precipitated solid was filtered off to obtain a compound (1-68-a) (0.734 g, yield 86%).

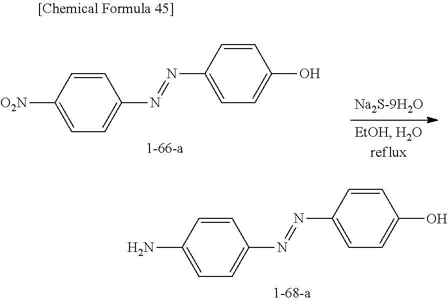 [SMILES: O=[N+]([O-])c1ccc(/N=N/c2ccc(O)cc2)cc1 ; Nc1ccc(/N=N/c2ccc(O)cc2)cc1]

### Synthesis of Compound (1-68-b)

The compound (1-68-a) (0.103 g, 0.482 mmol), 35% hydrochloric acid (10.15 mL, 1.7 mmol), acetic acid (0.50 mL), and water (0.5 mL) were mixed and cooled from 0° C. to 5° C., and a solution of sodium nitrite (37.6 mg, 0.545 mmol) in water (0.20 mL) was added dropwise thereto, and the mixture was stirred at 0° C. to 5° C. for 1 hour to prepare a diazo liquid. On the other hand, 2,5-difluorophenol (0.104 g, 0.785 mmol), sodium acetate (0.174 g, 2.12 mmol), and water (2.0 mL) were mixed and cooled from 0° C. to 5° C., the whole amount of the diazo liquid prepared above was poured and added dropwise, and the mixture was stirred for 1 day while maintaining the temperature from 0° C. to 5° C. After the temperature was raised to 40° C., the mixture was stirred for another 35 hours. The precipitated solid was filtered off to obtain a compound (1-68-b) (0.122 g, yield 62%).

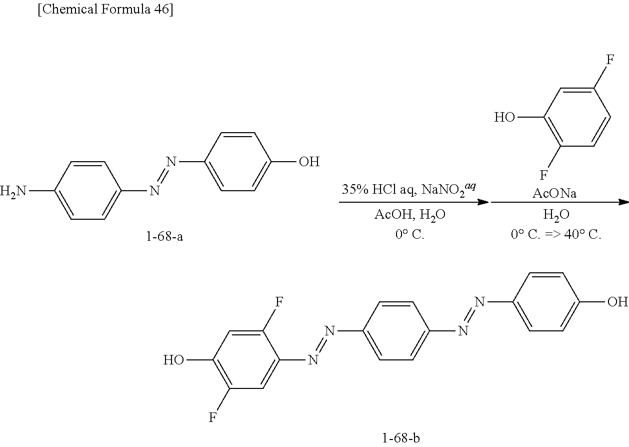 [SMILES: "AcONa" ; Nc1ccc(/N=N/c2ccc(O)cc2)cc1 ; Oc1cc(F)ccc1F ; Oc1ccc(/N=N/c2ccc(/N=N/c3cc(F)c(O)cc3F)cc2)cc1]

### Synthesis of Compound (1-68)

The compound (1-68-b) (0.109 g, 0.308 mmol), 1-iodo-2-methylpropane (0.182 g, 0.987 mmol), potassium carbonate (0.171 g, 1.21 mmol), and N,N-dimethylacetamide (3.0 mL) were mixed, and the mixture was heated and stirred at 100° C. for 2 hours. 1-Iodo-2-methylpropane (0.20 mL, 1.74 mmol) was added to the reaction solution, and the mixture was further heated and stirred for 30 minutes. Methanol was added to the reaction solution, and the precipitated solid was filtered off. The resulting solid was purified by preparative GPC using chloroform as a mobile phase, and further purified by reprecipitation from chloroform/methanol to obtain a compound (1-68) (0.0275 g, yield 19%).

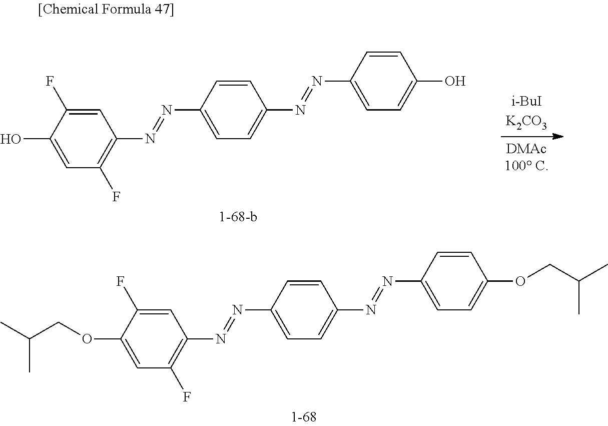 [SMILES: Oc1ccc(/N=N/c2ccc(/N=N/c3cc(F)c(O)cc3F)cc2)cc1 ; CC(C)COc1ccc(/N=N/c2ccc(/N=N/c3cc(F)c(OCC(C)C)cc3F)cc2)cc1]

¹H-NMR (400 MHz, CDCl₃): δ (ppm)=8.05-7.99 (m, 4H), 7.97-7.93 (m, 2H), 7.67 (dd, 1H), 7.04-7.00 (m, 2H), 3.86 (d, 2H), 3.83 (d, 2H), 2.20 (sept, 1H), 2.14 (sept, 1H), 1.07 (t, 12H).

The following compounds (2-1) and (2-2) were synthesized according to the process for producing compounds A-1 and B-1 described in JP-A-2017-197630.

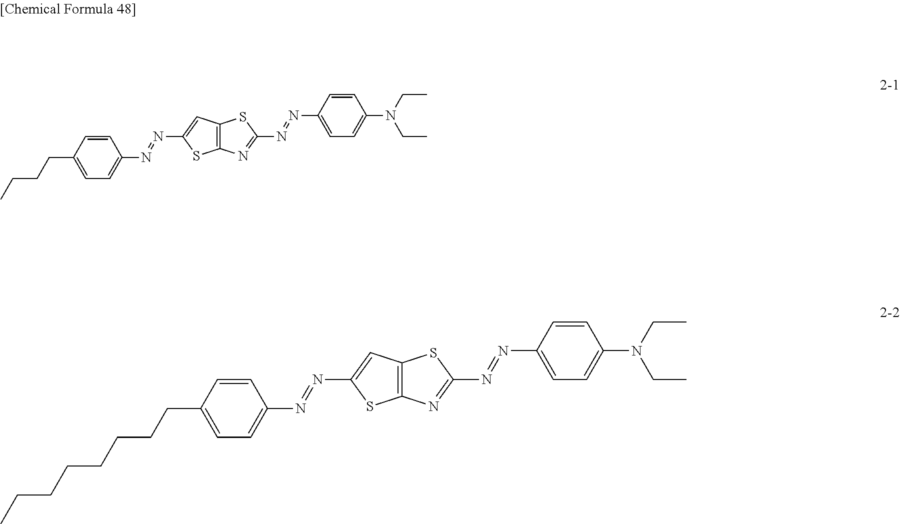

### Synthesis Example 11: Synthesis of Compound (2-8)

In order to synthesize a compound (2-8), a compound (2-8-a) was synthesized by a known diazo coupling method. Subsequently, silylation was performed to obtain the compound (2-8).

The compound (2-8-a) (0.139 g, 0.299 mmol) and imidazole (0.061 g, 0.90 mmol) were dissolved in N,N-dimethylformamide (5.0 mL), the solution was cooled to 0° C., chlorodimethyltexylsilane (0.112 g, 0.626 mmol) was then added thereto, the temperature was returned to normal temperature, and the mixture was stirred for 5 hours. Water was added to the reaction vessel, and the precipitated solid was filtered off and washed with methanol. The resulting solid was purified by silica gel column chromatography using chloroform as an eluent to obtain a compound (2-8) (0.130 g, yield 75%).

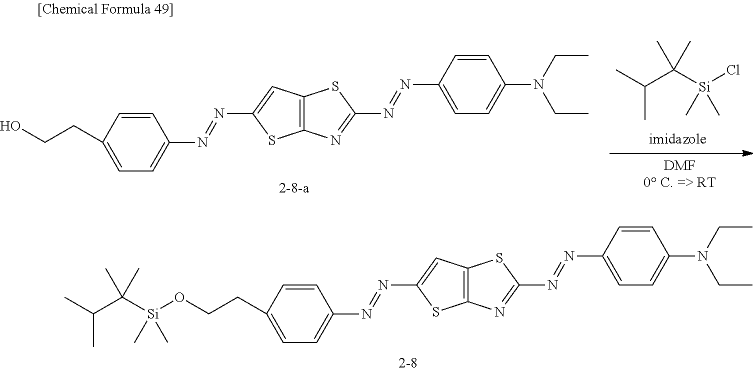

¹H-NMR (400 MHz, CDCl₃): δ (ppm)=7.95 (d, 2H), 7.91 (s, 1H), 7.80 (d, 2H), 7.33 (d, 2H), 6.75 (d, 2H), 3.84 (t, 2H), 3.52 (q, 4H), 2.88 (t, 2H), 1.63-1.58 (m, 1H), 1.28 (t, 6H), 0.86 (m, 6H), 0.82 (m, 6H), 0.03 (s, 6H)

### Example 1: Preparation of Composition E1 Containing Compound (1-1), Compound (2-1), and Compound (2-2)

The following components were mixed and then stirred at 80° C. for 1 hour, thus obtaining composition E1.
Polymerizable liquid crystal compound (A-6) 75 parts by mass
Polymerizable liquid crystal compound (A-7) 25 parts by mass
Compound (1-1) 2.0 parts by mass
Compound (2-1) 1.0 parts by mass
Compound (2-2) 1.0 parts by mass
Polymerization initiator: 2-dimethylamino-2-benzyl-1-(4-morpholinophenyl)butan-1-one (Irgacure 369; manufactured by BASF Japan Ltd.) 6 parts by mass
Leveling agent: polyacrylate compound (BYK-361N; manufactured by BYK-Chemie) 1.2 parts by mass
Solvent: o-xylene 250 parts by mass

Polymerizable Liquid Crystal Compound (A-6)

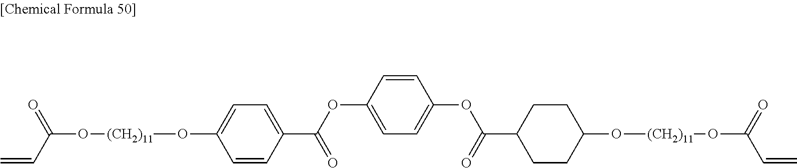

Polymerizable Liquid Crystal Compound (A-7)

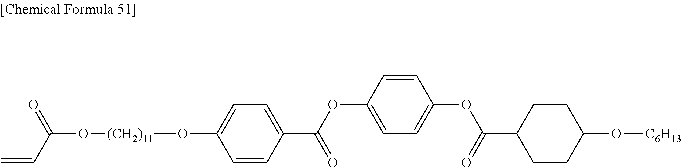

The polymerizable liquid crystal compound (A-6) was synthesized by the method described in Lub et al. Recl. Trav. Chim. Pays-Bas, 115, 321-328 (1996). The polymerizable liquid crystal compound (A-7) was produced in accordance with this method.

### <Examples 2 to 10>: Preparation of Compositions E2 to E10

Compositions E2 to E10 of Examples 2 to 10 were respectively obtained in the same manner as in Example 1 except that the compounds (1-2) to (1-5) and (1-64) to (1-68) were respectively used in place of the compound (1-1), and 2.0 parts by mass of the compound (2-8) was used in place of the compound (2-1) and the compound (2-2) in Examples 6 and 7.

### <Comparative Examples 1 and 2>: Preparation of Compositions C1 and C2

Compositions C1 and C2 of Comparative Examples 1 and 2 were obtained, respectively, in the same manner as in Example 1 except that compound (3-1) or (3-2) represented by the following formula was used in place of the compound (1-1). The following compounds (3-1) and (3-2) were synthesized according to the method described in the above Synthesis Example.

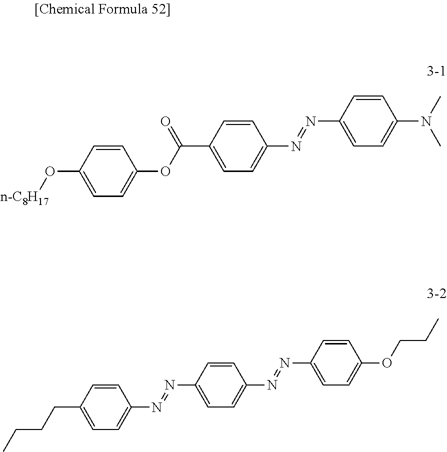

### <Production of Polarizing Plate>

### 1. Formation of Orientation Film

A glass substrate was used as a transparent substrate. An aqueous solution (composition for orientation layer formation) of 2 mass % polyvinyl alcohol (Polyvinyl Alcohol 1000 perfectly saponified type, manufactured by Wako Pure Chemical Industries, Ltd.) was applied onto a glass base board by a spin coating method and then dried. Then, a film having a thickness of 100 nm was formed. Subsequently, a surface of the obtained film was subjected to rubbing treatment, thus forming an orientation film, and a substrate having the orientation film formed on the glass substrate was obtained.

### 2. Formation of Polarizing Film

The composition obtained above was applied onto the orientation film of the substrate obtained above by a spin coating method, heated and dried on a hot plate at 120° C. for 3 minutes, and then rapidly cooled to 70° C. (temperature exhibiting a smectic liquid crystal phase at the time of temperature decrease) or lower to obtain a laminate having a dry film formed on the orientation film.

Then, the dry film was irradiated with ultraviolet rays in an exposure amount of 2400 mJ/cm² (standard 365 nm) using a UV irradiation apparatus (SPOT CURE SP-7; manufactured by Ushio Inc.), so that the polymerizable liquid crystal compound contained in the dry film was polymerized with retaining the liquid crystal state of the composition, thereby forming a polarizing film from the dry film and obtaining a polarizing plate.

### <Evaluation>

The dichroic ratio of the obtained polarizing plate was measured as follows. An absorbance (A1) in a transmission axis direction and an absorbance (A2) in an absorption axis direction in the maximum absorption wavelength (Amax) in the wavelength range of 570 nm or more and 700 nm or less of the polarizing film of the polarizing plate were measured by a double beam method using a device in which a folder provided with the polarizing plate was set in a spectrophotometer (UV-3150, manufactured by Shimadzu Corporation). In the folder, a mesh for cutting a light amount by 50% was installed on a reference side. A ratio (A2/A1) was calculated from the values the absorbance (A1) in the transmission axis direction and the absorbance (A2) in the absorption axis direction thus measured, and taken as the dichroic ratio before a light fastness test (DR0).

A protective film (40 μm TAC (“KC4UY” manufactured by Konica Minolta, Inc.)) was disposed on a surface of the formed polarizing film, and light was irradiated from the upper side under the following conditions, whereby the light resistance was evaluated. The dichroic ratio at the maximum absorption wavelength (Amax) in the range of 570 nm or more and 700 nm or less after the light fastness test was calculated and taken as a dichroic ratio (DR1) after the light fastness test. In addition, the dichroic ratio (DR1) after the light fastness test was divided by the dichroic ratio (DR0) before the light fastness test to obtain a percentage, and the percentage was defined as a dichroic ratio maintenance ratio (%). Results are shown in Table 1. When the dichroic ratio maintenance ratio exceeds 95%, it is determined that the polarizing film is good.

The light irradiation conditions in the light resistance test are as follows.

Equipment used: Ci 4000 manufactured by Atlas Material Testing Solutions

Light source used: xenon arc lamp

Exposure condition: 120 W/m² (300 nm-400 nm)

Test time: 20 hours

Exposure dose: 8640 KJ/m²

Temperature: 65° C.

TABLE 1

| | | | Dichroic | Dichroic | |
|---|---|---|---|---|---|
| | | | ratio | ratio | Dichroic |
| | | | before | after | ratio |
| | | | light | light | mainte- |
| | First | Second | fastness | fastness | nance |
| | compound | compound | test | test | ratio |
| Example 1 | 1-1 | 2-1/2-2 | 73.3 | 70.8 | 97% |
| Example 2 | 1-2 | 2-1/2-2 | 75.9 | 74.6 | 98% |
| Example 3 | 1-3 | 2-1/2-2 | 74.4 | 74.3 | >99% |
| Example 4 | 1-4 | 2-1/2-2 | 80.6 | 77.9 | 97% |
| Example 5 | 1-5 | 2-1/2-2 | 75.6 | 72.9 | 96% |
| Example 6 | 1-64 | 2-8 | 72.6 | 70.2 | 97% |
| Example 7 | 1-65 | 2-8 | 68.8 | 66.3 | 96% |
| Example 8 | 1-66 | 2-1/2-2 | 73.2 | 73.0 | >99% |
| Example 9 | 1-67 | 2-1/2-2 | 84.9 | 84.9 | >99% |
| Example 10 | 1-68 | 2-1/2-2 | 67.4 | 66.8 | 99% |
| Comparative | 3-1 | 2-1/2-2 | 77.1 | 69.8 | 91% |
| Example 1 | | | | | |
| Comparative | 3-2 | 2-1/2-2 | 82.5 | 76.2 | 92% |
| Example 2 | | | | | |

Table 1 shows that the polarizing plate including the film including the composition containing the first compound and the second compound as the forming material can achieve an excellent dichroic ratio maintenance ratio.

1. A composition comprising:
a first compound represented by the following formula (1);
a second compound having a maximum absorption wavelength in a wavelength range of 550 nm or more and 650 nm or less and represented by the following formula (2); and
a liquid crystalline compound including at least one of a polymerizable liquid crystal compound and a liquid crystalline polymer compound: 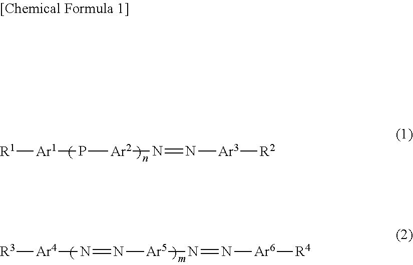
wherein n and m each independently represent 1 or 2,
R¹ and R³ each independently represent a substituent,
R² and R⁴ each independently represent one group selected from the group consisting of an alkylamino group, an alkoxy group, and an alkylthio group, and a hydrogen atom of these groups is optionally substituted with a polymerizable group,
P represents a single bond or at least one group selected from the group consisting of —OC(═O)—, —C(═O)O—, —NHC(═O)—, —C(═O)NH—, —C≡C—, —CH═CH—, —CH═N—, —N═N—, and —N═CH—,
Ar¹, Ar², and Ar³ each independently represent a 1,4-phenylene group or a divalent sulfur-containing aromatic heterocyclic group optionally having, as a substituent, at least one selected from the group consisting of a halogen atom, a hydroxy group, a methyl group, and a methoxy group,
at least one of Ar¹ and Ar² has a fluorine atom as a substituent,
provided that when Ar² has a fluorine atom and there are two Ar²s, at least one Ar² optionally has a fluorine atom,
Ar⁴, Ar⁵, and Ar⁶ each independently represent a 1,4-phenylene group, a naphthalenediyl group, or a divalent sulfur-containing aromatic heterocyclic group optionally having, as a substituent, at least one selected from the group consisting of a halogen atom, a hydroxy group, a methyl group, and a methoxy group,
when n is 2, two Ar²s and two Ps are optionally the same or different to each other, and
when m is 2, two Ar⁵s are optionally the same or different to each other.

2. The composition according to claim 1, wherein in the formula (2), at least one of Ar⁴, Ar⁵, and Ar⁶ represents a divalent sulfur-containing aromatic heterocyclic group.

3. The composition according to claim 1, wherein in the formula (2), at least one of Ar⁴, Ar⁵, and Ar⁶ represents a thieno [2,3-d] thiazole-2,5-diyl group.

4. The composition according to claim 1, wherein in the formula (1), P represents a single bond or at least one group selected from the group consisting of —OC(═O)—, —C(═O)O—, —NHC(═O)—, —C(═O)NH—, and —N═N—.

5. The composition according to claim 1, wherein the liquid crystalline compound is a smectic liquid crystalline compound.

6. A film comprising the composition according to claim 1 as a forming material.

7. A laminate comprising the film according to claim 6.

8. A display device comprising the laminate according to claim 7.
